(19) United States
(12) Patent Application Publication
(10) Pub. No.: US 2003/0087181 A1
(43) Pub. Date: May 8, 2003

(54) Polymers, resist compositions and patterning process

(75) Inventors: Tsunehiro Nishi, Nakakubiki-gun (JP); Tomohiro Kobayashi, Nakakubiki-gun (JP)

Correspondence Address: MILLEN, WHITE, ZELANO & BRANIGAN, P.C., 2200 CLARENDON BLVD., SUITE 1400, ARLINGTON, VA, 22201, US

(73) Assignee: Shin-Etsu Chemical Co., Ltd., Tokyo (JP)

(21) Appl. No.: 10/150,083

(22) Filed: May 20, 2002

(30) Foreign Application Priority Data
May 21, 2001 (JP) 2001-150535

(51) Int. Cl. G03F 7/004

(52) U.S. Cl. 430/270.1; 430/326

(57) ABSTRACT

A polymer comprising recurring units of formulae (1) and (2) wherein W is a divalent C₂₋₁₅ group which forms a 5- or 6-membered cyclic ether, cyclic ketone, lactone, cyclic carbonate, cyclic acid anhydride or cyclic imide, k is 0 or 1, and Y is —O— or —(NR¹)— wherein R¹ is H or C₁₋₁₅ alkyl and units which are decomposable under acidic conditions to generate carboxylic acid, and having a Mw of 1,000-500,000 is novel. A resist composition comprising the polymer as a base resin is sensitive to high-energy radiation, has excellent sensitivity, resolution and etching resistance and lends itself to micropatterning with electron beams or deep-UV.

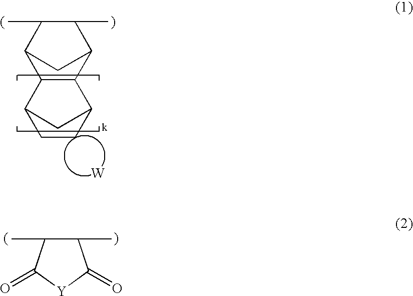

This invention relates to (i) a polymer comprising specific recurring units, (ii) a resist composition comprising the polymer as a base resin, and (iii) a patterning process using the resist composition.

### BACKGROUND OF THE INVENTION

While a number of recent efforts are being made to achieve a finer pattern rule in the drive for higher integration and operating speeds in LSI devices, deep-ultraviolet lithography is thought to hold particular promise as the next generation in microfabrication technology. In particular, photolithography using a KrF or ArF excimer laser as the light source is strongly desired to reach the practical level as the micropatterning technique capable of achieving a feature size of 0.3 μm or less.

For resist materials for use with a KrF excimer lasers, polyhydroxystyrene having a practical level of transmittance and etching resistance is, in fact, a standard base resin. For resist materials for use with ArF excimer lasers, polyacrylic or polymethacrylic acid derivatives and polymers containing aliphatic cyclic compounds in the backbone are under investigation. All these polymers have advantages and disadvantages, and none of them have been established as the standard base resin.

More particularly, resist compositions using derivatives of polyacrylic or polymethacrylic acid have the advantages of high reactivity of acid-decomposable groups and good substrate adhesion and give relatively satisfactory results with respect to sensitivity and resolution, but have extremely low etching resistance and are impractical because the resin backbone is weak. On the other hand, resist compositions using polymers containing alicyclic compounds in their backbone have a practically acceptable level of etching resistance because the resin backbone is robust, but are very low in sensitivity and resolution because the reactivity of acid-decomposable protective groups is extremely low as compared with those on the (meth)acrylic polymers. These compositions are thus impractical as well.

Independent of whether the resist is based on (meth)acrylic resins or alicyclic backbone resins, there is a common problem of line density dependency that when a pattern to be transferred includes dense and sparse regions, it is impossible to produce the desired pattern in both the dense and sparse regions at the same exposure. More particularly, with respect to the formation of a line-and-space pattern, for example, if solitary lines are formed at an exposure that can resolve crowded lines with good size control, they are finished to a line width less than the desired size. Presumably this phenomenon is ascribable to the increased diffusion length of acid generated upon exposure. There is a tendency that the diffusion of the generated acid is enhanced as the system becomes more hydrophobic. Since both (meth)acrylic resins and alicyclic backbone resins have increased their carbon density in order to improve etching resistance, the diffusion of the generated acid is more promoted as a result, exaggerating line density dependency. Then at the very fine pattern size for which an ArF excimer laser is actually used, a resist material having substantial line density dependency cannot be used in an industrially acceptable manner because solitary lines can disappear. While a finer pattern rule is being demanded, there is a need to have a resist material which is not only satisfactory in sensitivity, resolution, and etching resistance, but also minimized in line density dependency.

### SUMMARY OF THE INVENTION

Therefore, an object of the present invention is to provide (i) a polymer having improved reactivity, robustness and substrate adhesion as well as controlled diffusion of acid generated upon exposure, (ii) a resist composition comprising the polymer as a base resin, which has a higher resolution and etching resistance than conventional resist compositions and minimized line density dependency, and (iii) a patterning process using the resist composition.

It has been found that polymers comprising recurring units of the following general formulae (1) and (2) and units of one or more types that are decomposable under acidic conditions to generate carboxylic acid, and having a weight average molecular weight of 1,000 to 500,000, which are produced by the method to be described later, have improved reactivity, robustness or rigidity and substrate adhesion; that a resist composition comprising the polymer as the base resin has a high resolution and etching resistance and minimized line density dependency; and that this resist composition lends itself to precise micropatterning.

In a first aspect, the invention provides a polymer comprising recurring units of the following general formulae (1) and (2) and units of at least one type which are decomposable under acidic conditions to generate carboxylic acid, and having a weight average molecular weight of 1,000 to 500,000.

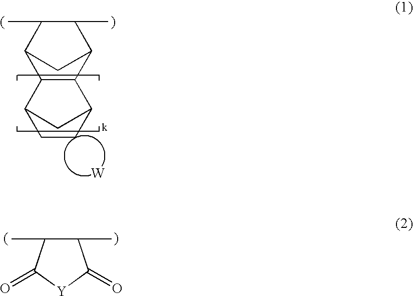

Herein W is a divalent group having 2 to 15 carbon atoms which forms a cyclic ether, cyclic ketone, lactone, cyclic carbonate, cyclic acid anhydride or cyclic imide of 5- or 6-membered ring with the carbon atom to which it is bonded; k is 0 or 1; and Y is —O— or —(NR¹)— wherein R¹ is hydrogen or a straight, branched or cyclic alkyl group of 1 to 15 carbon atoms.

In a preferred embodiment, the units of at least one type which are decomposable under acidic conditions to generate carboxylic acid include recurring units of the following general formula (3).

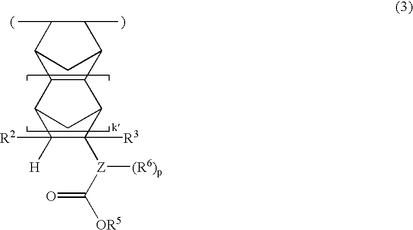

Herein R² is hydrogen, methyl or CH₂CO₂R⁴; R³ is hydrogen, methyl or CO₂R⁴; R⁴ which may be identical or different in R² and R³ is a straight, branched or cyclic alkyl group of 1 to 15 carbon atoms; R⁵ is an acid labile group; R⁶ is selected from the class consisting of a halogen atom, a hydroxyl group, a straight, branched or cyclic alkoxy, acyloxy or alkylsulfonyloxy group of 1 to 15 carbon atoms, and a straight, branched or cyclic alkoxycarbonyloxy or alkoxyalkoxy group of 2 to 15 carbon atoms, in which some or all of the hydrogen atoms on constituent carbon atoms may be substituted with halogen atoms; Z is a single bond or a straight, branched or cyclic (p+2)-valent hydrocarbon group of 1 to 5 carbon atoms, in which at least one methylene may be substituted with oxygen to form a chain-like or cyclic ether or two hydrogen atoms on a common carbon may be substituted with oxygen to form a ketone; k′ is 0 or 1; and

p is 0, 1 or 2.

In another preferred embodiment, the units of at least one type which are decomposable under acidic conditions to generate carboxylic acid include recurring units of the following general formula (4).

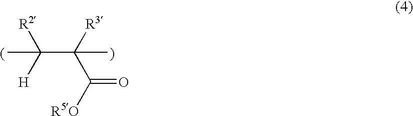

Herein R^{2′} is hydrogen, methyl or CH₂CO₂R^{4′}; R^{3′} is hydrogen, methyl or CO₂R^{4′}; R^{4′} which may be identical or different in R^{2′} and R^{3′} is a straight, branched or cyclic alkyl group of 1 to 15 carbon atoms; and R^{5′} is an acid labile group.

In a second aspect, the invention provides a resist composition comprising the inventive polymer.

In a third aspect, the invention provides a process for forming a resist pattern comprising the steps of applying the resist composition onto a substrate to form a coating; heat treating the coating and then exposing it to high-energy radiation or electron beams through a photo mask; and optionally heat treating the exposed coating and developing it with a developer.

The polymer comprising recurring units of formula (1) has high robustness due to the inclusion of a bridged aliphatic ring in the backbone. It also has improved substrate adhesion due to the inclusion of a cyclic polar structure, specifically a cyclic ether, cyclic ketone, lactone, cyclic carbonate, cyclic acid anhydride or cyclic imide. Since this cyclic polar structure is introduced in the form of a spiro ring directly attached to the aliphatic ring, the polymer is less hydrophobic as a whole than those polymers in which the cyclic polar structure is introduced through a spacer such as alkylene or ester bond, and hence, has a very high ability to restrain acid diffusion. Therefore, a resist composition using the inventive polymer as a base resin satisfies all the performance factors of sensitivity, resolution and etching resistance, is minimized in line density dependency, and is thus very useful in forming micropatterns.

### DESCRIPTION OF THE PREFERRED EMBODIMENTS

### Polymer

Polymers or high molecular weight compounds comprising recurring units of the following general formulae (1) and (2) and units of one or more types which are decomposable under acidic conditions to generate carboxylic acid according to the invention are novel. The polymers have a weight average molecular weight of 1,000 to 500,000.

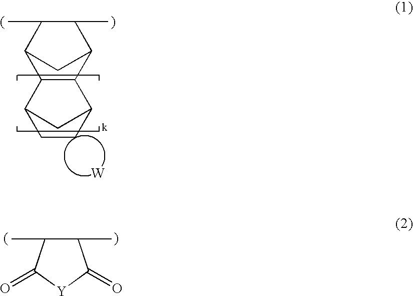

Herein W is a divalent group having 2 to 15 carbon atoms which forms a cyclic ether, cyclic ketone, lactone, cyclic carbonate, cyclic acid anhydride or cyclic imide of 5- or 6-membered ring with the carbon atom to which it is bonded, and k is 0 or 1. Examples of the cyclic structure formed by W are given below.

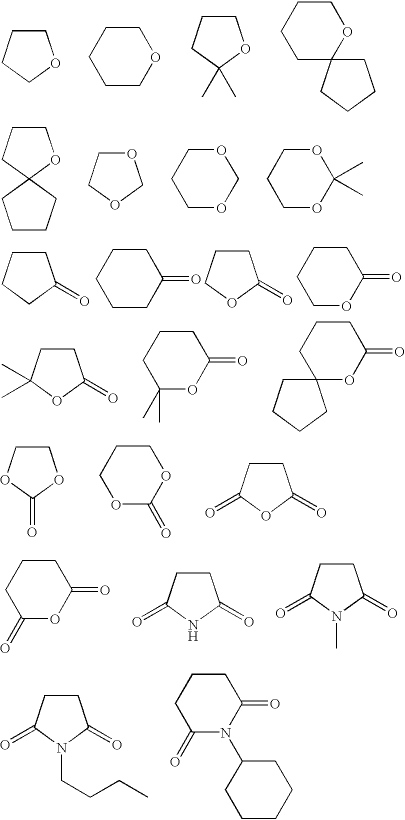

Y is —O— or —(NR¹)—. R¹ is hydrogen or a straight, branched or cyclic alkyl group of 1 to 15 carbon atoms, for example, methyl, ethyl, propyl, isopropyl, n-butyl, sec-butyl, tert-butyl, tert-amyl, n-pentyl, n-hexyl, cyclopentyl, cyclohexyl, ethylcyclopentyl, butylcyclopentyl, ethylcyclohexyl, butylcyclohexyl, adamantyl, ethyladamantyl, and butyladamantyl.

More specifically, the polymers of the invention are divided into the following two subgenuses of polymers.

Subgenus (I) includes polymers in which the units of at least one type which are decomposable under acidic conditions to generate carboxylic acid are recurring units of the following general formula (3).

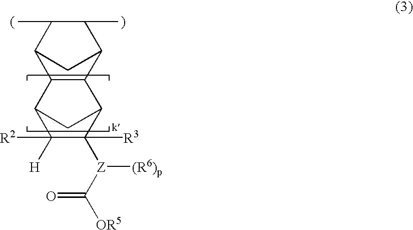

Herein R² is hydrogen, methyl or CH₂CO₂R⁴; R³ is hydrogen, methyl or CO₂R⁴; R⁴ which may be identical or different in R² and R³ is a straight, branched or cyclic alkyl group of 1 to 15 carbon atoms; R⁵ is an acid labile group; R⁶ is selected from the class consisting of a halogen atom, a hydroxyl group, a straight, branched or cyclic alkoxy, acyloxy or alkylsulfonyloxy group of 1 to 15 carbon atoms, and a straight, branched or cyclic alkoxycarbonyloxy or alkoxyalkoxy group of 2 to 15 carbon atoms, in which some or all of the hydrogen atoms on constituent carbon atoms may be substituted with halogen atoms; Z is a single bond or a straight, branched or cyclic (p+2)-valent hydrocarbon group of 1 to 5 carbon atoms, in which at least one methylene may be substituted with oxygen to form a chain-like or cyclic ether or two hydrogen atoms on a common carbon may be substituted with oxygen to form a ketone; k′ is 0 or 1; and p is 0, 1 or 2.

Subgenus (II) includes polymers in which the units of at least one type which are decomposable under acidic conditions to generate carboxylic acid are recurring units of the following general formula (4).

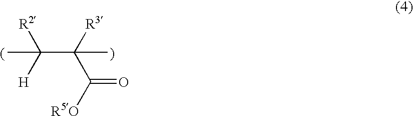

Herein R^{2′} is hydrogen, methyl or CH₂CO₂R^{4′}; R^{3′} is hydrogen, methyl or CO₂R^{4′}; R^{4′} which may be identical or different in R^{2′} and R^{3′} is a straight, branched or cyclic alkyl group of 1 to 15 carbon atoms; and R^{5′} is an acid labile group.

More particularly, R² is hydrogen, methyl or CH₂CO₂R⁴, and R^{2′} is hydrogen, methyl or CH₂CO₂R^{4′}. R³ is hydrogen, methyl or CO₂R⁴, and R^{3′} is hydrogen, methyl or CO₂R^{4′}. R⁴ and R^{4′} which may be identical or different between R² and R³ and between R^{2′} and R^{3′}, respectively, stand for straight, branched or cyclic alkyl groups of 1 to 15 carbon atoms, such as, for example, methyl, ethyl, propyl, isopropyl, n-butyl, sec-butyl, tert-butyl, tert-amyl, n-pentyl, n-hexyl, cyclopentyl, cyclohexyl, ethylcyclopentyl, butylcyclopentyl, ethylcyclohexyl, butylcyclohexyl, adamantyl, ethyladamantyl and butyladamantyl. R⁵ and R ^{5′} stand for acid labile groups to be described later.

R⁶ is selected from among a halogen atom, a hydroxyl group, a straight, branched or cyclic alkoxy, acyloxy or alkylsulfonyloxy group of 1 to 15 carbon atoms, and a straight, branched or cyclic alkoxycarbonyloxy or alkoxyalkoxy group of 2 to 15 carbon atoms, in which some or all of the hydrogen atoms on constituent carbon atoms may be substituted with halogen atoms. Exemplary of R⁶ are fluoro, chloro, bromo, hydroxyl, methoxy, ethoxy, propoxy, isopropoxy, n-butoxy, sec-butoxy, tert-butoxy, tert-amyloxy, n-pentoxy, n-hexyloxy, cyclopentyloxy, cyclohexyloxy, ethylcyclopentyloxy, butylcyclopentyloxy, ethylcyclohexyloxy, butylcyclohexyloxy, adamantyloxy, ethyladamantyloxy, butyladamantyloxy, formyloxy, acetoxy, ethylcarbonyloxy, pivaloyloxy, methanesulfonyloxy, ethanesulfonyloxy, n-butanesulfonyloxy, trifluoroacetoxy, trichloroacetoxy, 3,3,3-trifluoroethylcarbonyloxy, methoxymethoxy, 1-ethoxyethoxy, 1-ethoxypropoxy, 1-tert-butoxyethoxy, 1-cyclohexyl-oxyethoxy, 2-tetrahydrofuranyloxy, 2-tetrahydropyranyloxy, methoxycarbonyloxy, ethoxycarbonyloxy, and tert-butoxycarbonyloxy.

Z is a single bond or a straight, branched or cyclic (p+2)-valent hydrocarbon group of 1 to 5 carbon atoms, in which at least one methylene may be substituted with oxygen to form a chain-like or cyclic ether or two hydrogen atoms on a common carbon may be substituted with oxygen to form a ketone. In case of p=0, for example, exemplary Z groups are methylene, ethylene, trimethylene, tetramethylene, pentamethylene, 1,2-propanediyl, 1,3-butanediyl, 1-oxo-2-oxapropane-1,3-diyl, and 3-methyl-1-oxo-2-oxabutane-1,4-diyl. In case of p≠0, exemplary Z groups are (p+2)-valent groups obtained by eliminating one or two hydrogen atoms from the above-exemplified groups.

The acid labile groups represented by R⁵ and R^{5′} may be selected from a variety of such groups. Examples of the acid labile group are groups of the following general formulae (L1) to (L4), tertiary alkyl groups of 4 to 20 carbon atoms, preferably 4 to 15 carbon atoms, trialkylsilyl groups in which each alkyl moiety has 1 to 6 carbon atoms, and oxoalkyl groups of 4 to 20 carbon atoms.

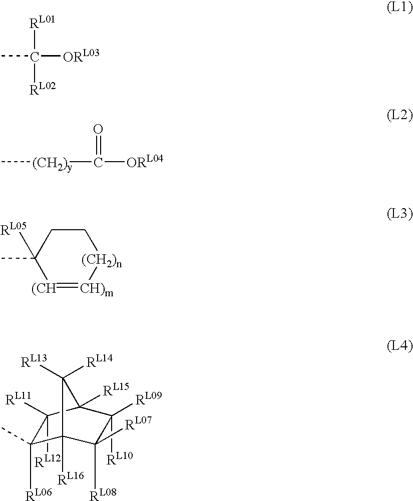

In these formulae and throughout the specification, the broken line denotes a free valence bond. R^{L01} and R^{L02} are hydrogen or straight, branched or cyclic alkyl groups of 1 to 18 carbon atoms, preferably 1 to 10 carbon atoms. Exemplary alkyl groups include methyl, ethyl, propyl, isopropyl, n-butyl, sec-butyl, tert-butyl, cyclopentyl, cyclohexyl, 2-ethylhexyl, and n-octyl. R^{L03} is a monovalent hydrocarbon group of 1 to 18 carbon atoms, preferably 1 to 10 carbon atoms, which may contain a hetero atom such as oxygen, examples of which include unsubstituted straight, branched or cyclic alkyl groups and straight, branched or cyclic alkyl groups in which some hydrogen atoms are replaced by hydroxyl, alkoxy, oxo, amino, alkylamino or the like. Illustrative examples are the substituted alkyl groups shown below.

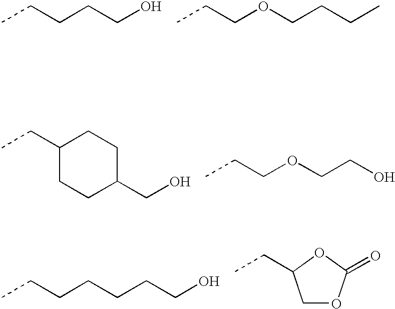

A pair of R^{L01} and R^{L02}, R^{L01} and R^{L03}, or R^{L02} and R^{L03} may form a ring. Each of R^{L01}, R^{L02} and R^{L03} is a straight or branched alkylene group of 1 to 18 carbon atoms, preferably 1 to 10 carbon atoms when they form a ring.

R^{L04} is a tertiary alkyl group of 4 to 20 carbon atoms, preferably 4 to 15 carbon atoms, a trialkylsilyl group in which each alkyl moiety has 1 to 6 carbon atoms, an oxoalkyl group of 4 to 20 carbon atoms, or a group of formula (L1). Exemplary tertiary alkyl groups are tert-butyl, tert-amyl, 1,1-diethylpropyl, 2-cyclopentylpropan-2-yl, 2-cyclohexylpropan-2-yl, 2-(bicyclo[2.2.1]heptan-2-yl)propan-2-yl, 2-(adamantan-1-yl)propan-2-yl, 1-ethylcyclopentyl, 1-butylcyclopentyl, 1-ethylcyclohexyl, 1-butylcyclohexyl, 1-ethyl-2-cyclopentenyl, 1-ethyl-2-cyclohexenyl, 2-methyl-2-adamantyl, and 2-ethyl-2-adamantyl. Exemplary trialkylsilyl groups are trimethylsilyl, triethylsilyl, and dimethyl-tert-butylsilyl. Exemplary oxoalkyl groups are 3-oxocyclohexyl, 4-methyl-2-oxooxan-4-yl, and 5-methyl-2-oxooxolan-5-yl. Letter y is an integer of 0 to 6.

R^{L05} is a monovalent hydrocarbon group of 1 to 8 carbon atoms which may contain a hetero atom or a substituted or unsubstituted aryl group of 6 to 20 carbon atoms. Examples of the monovalent hydrocarbon group which may contain a hetero atom include straight, branched or cyclic alkyl groups such as methyl, ethyl, propyl, isopropyl, n-butyl, sec-butyl, tert-butyl, tert-amyl, n-pentyl, n-hexyl, cyclopentyl, and cyclohexyl, and substituted groups in which some hydrogen atoms on the foregoing groups are substituted with hydroxyl, alkoxy, carboxy, alkoxycarbonyl, oxo, amino, alkylamino, cyano, mercapto, alkylthio, sulfo or other groups. Exemplary aryl groups are phenyl, methylphenyl, naphthyl, anthryl, phenanthryl, and pyrenyl. Letter m is equal to 0 or 1, n is equal to 0, 1, 2 or 3, and 2m+n is equal to 2 or 3.

R^{L06} is a monovalent hydrocarbon group of 1 to 8 carbon atoms which may contain a hetero atom or a substituted or unsubstituted aryl group of 6 to 20 carbon atoms. Examples of these groups are the same as exemplified for R^{L05}.

R^{L07} to R^{L16} independently represent hydrogen or monovalent hydrocarbon groups of 1 to 15 carbon atoms which may contain a hetero atom. Exemplary hydrocarbon groups are straight, branched or cyclic alkyl groups such as methyl, ethyl, propyl, isopropyl, n-butyl, sec-butyl, tert-butyl, tert-amyl, n-pentyl, n-hexyl, n-octyl, n-nonyl, n-decyl, cyclopentyl, cyclohexyl, cyclopentylmethyl, cyclopentylethyl, cyclopentylbutyl, cyclohexylmethyl, cyclohexylethyl and cyclohexylbutyl, and substituted ones of these groups in which some hydrogen atoms are replaced by hydroxyl, alkoxy, carboxy, alkoxycarbonyl, oxo, amino, alkylamino, cyano, mercapto, alkylthio, sulfo or other groups. Alternatively, R^{L07} to R^{L16}, taken together, form a ring (for example, a pair of R^{L07} and R^{L08}, R^{L07} and R^{L09}, R^{L08} and R^{L10}, R^{L09} and R^{L10}, R^{L11} and R^{L12}, R^{L13} and R^{L14}, or a similar pair form a ring). Each of R^{L07} to R^{L16} represents a divalent C₁-C₁₅ hydrocarbon group which may contain a hetero atom, when they form a ring, examples of which are the ones exemplified above for the monovalent hydrocarbon groups, with one hydrogen atom being eliminated. Two of R^{L07} to R^{L16} which are attached to adjoining carbon atoms (for example, a pair of R^{L07} and R^{L09}, R^{L09} and R^{L15}, R^{L13} and R^{L15}, or a similar pair) may bond together directly to form a double bond.

Of the acid labile groups of formula (L1), the straight and branched ones are exemplified by the following groups.

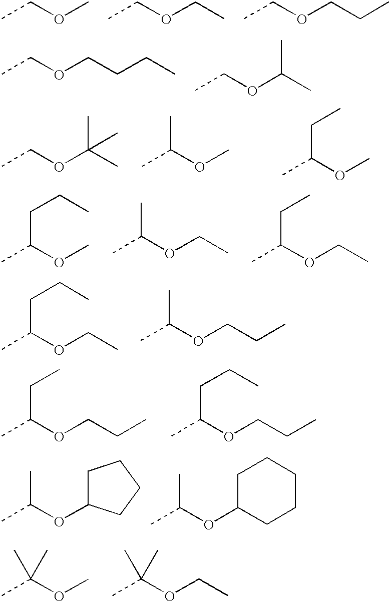

Of the acid labile groups of formula (L1), the cyclic ones are, for example, tetrahydrofuran-2-yl, 2-methyltetrahydrofuran-2-yl, tetrahydropyran-2-yl, and 2-methyltetrahydropyran-2-yl.

Examples of the acid labile groups of formula (L2) include tert-butoxycarbonyl, tert-butoxycarbonylmethyl, tert-amyloxycarbonyl, tert-amyloxycarbonylmethyl, 1,1-diethylpropyloxycarbonyl, 1,1-diethylpropyloxycarbonylmethyl, 1-ethylcyclopentyloxycarbonyl, 1-ethylcyclopentyloxycarbonylmethyl, 1-ethyl-2-cyclopentenyloxycarbonyl, 1-ethyl-2-cyclopentenyloxycarbonylmethyl, 1-ethoxyethoxycarbonylmethyl, 2-tetrahydropyranyloxycarbonylmethyl, and 2-tetrahydrofuranyloxycarbonylmethyl groups.

Examples of the acid labile groups of formula (L3) include 1-methylcyclopentyl, 1-ethylcyclopentyl, 1-n-propylcyclopentyl, 1-isopropylcyclopentyl, 1-n-butylcyclopentyl, 1-sec-butylcyclopentyl, 1-cyclohexylcyclopentyl, 1-(4-methoxy-n-butyl)cyclopentyl, 1-methylcyclohexyl, 1-ethylcyclohexyl, 3-methyl-1-cyclopenten-3-yl, 3-ethyl-1-cyclopenten-3-yl, 3-methyl-1-cyclohexen-3-yl, and 3-ethyl-1-cyclohexen-3-yl groups.

The acid labile groups of formula (L4) are exemplified by the following groups.

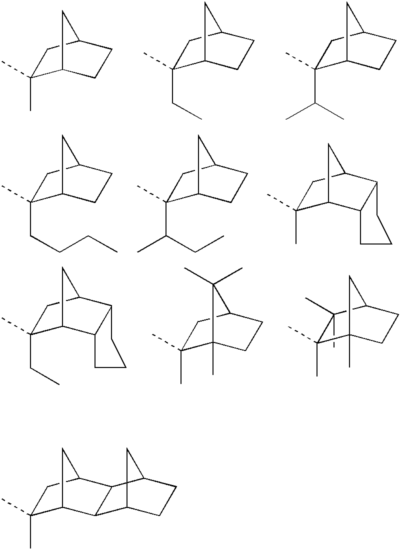

Examples of the tertiary alkyl groups of 4 to 20 carbon atoms, trialkylsilyl groups in which each alkyl moiety has 1 to 6 carbon atoms, and oxoalkyl groups of 4 to 20 carbon atoms are as exemplified for R^{L04}.

Illustrative, non-limiting, examples of the recurring units of formula (1) are given below.

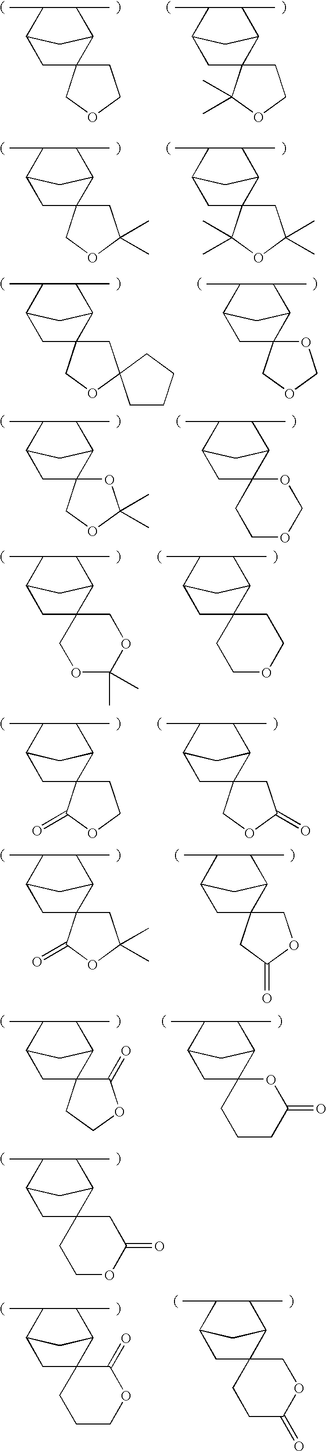

Illustrative, non-limiting, examples of the recurring units of formula (3) are given below.

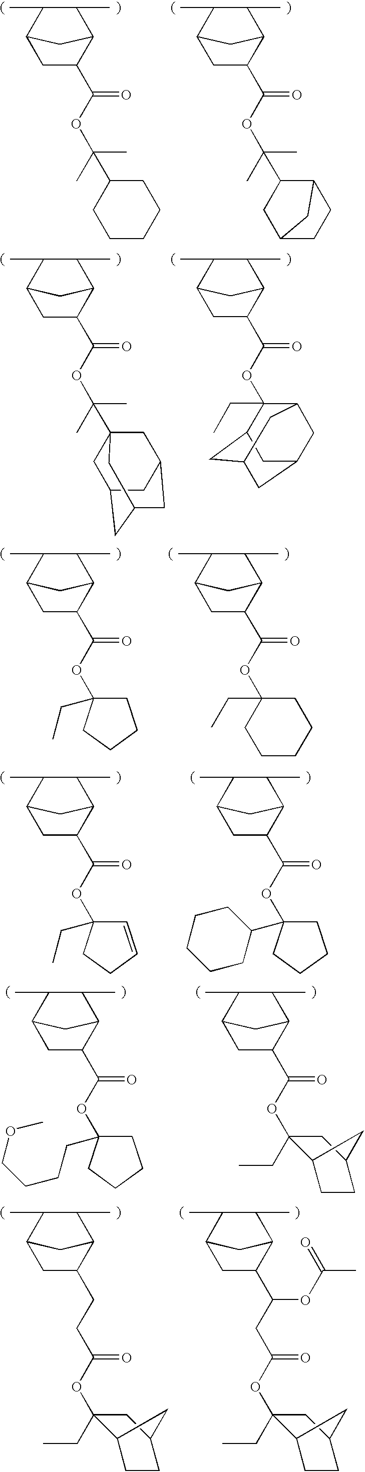

Illustrative, non-limiting, examples of the recurring units of formula (4) are given below.

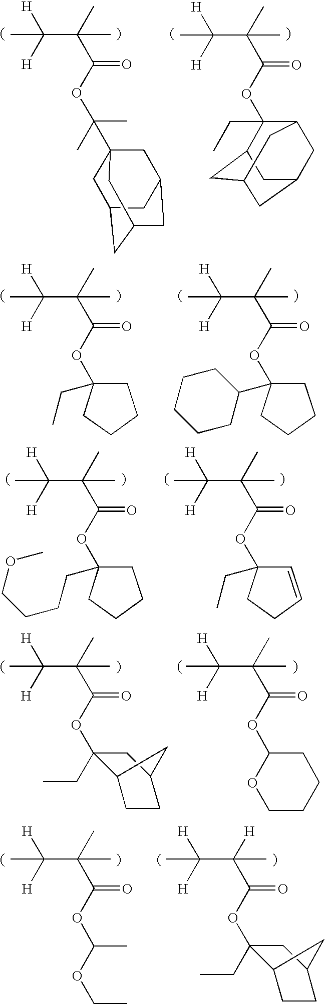

If desired, the polymers of the invention may further contain recurring units of one or more types selected from units of the following general formulae (M1) to (M8).

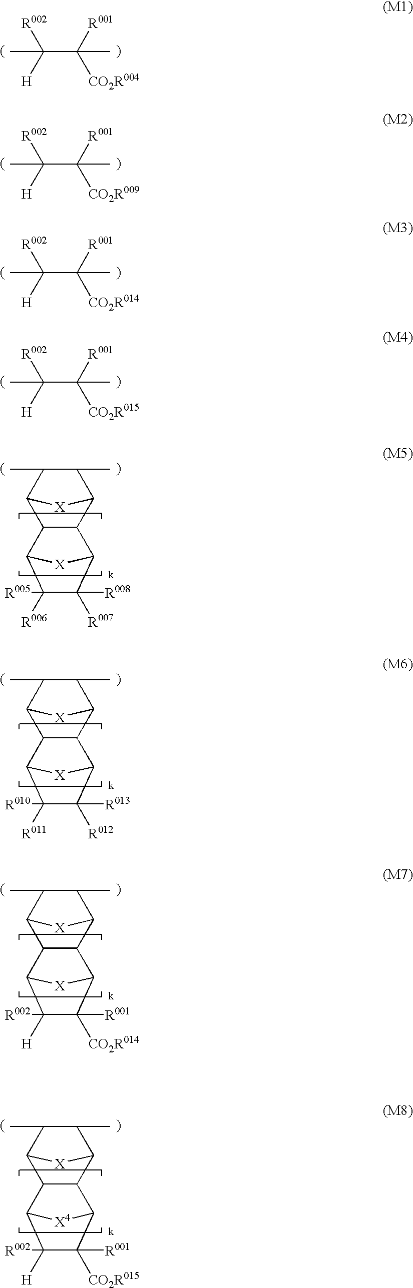

Herein, R⁰⁰¹ is hydrogen, methyl or CH₂CO₂R⁰⁰³. R⁰⁰² is hydrogen, methyl or CO₂R⁰⁰³. R⁰⁰³ is a straight, branched or cyclic alkyl group of 1 to 15 carbon atoms. R⁰⁰⁴ is hydrogen or a monovalent hydrocarbon group of 1 to 15 carbon atoms having a carboxyl or hydroxyl group. At least one of R⁰⁰⁵ to R⁰⁰⁸ represents a monovalent hydrocarbon group of 1 to 15 carbon atoms having a carboxyl or hydroxyl group while the remaining R's independently represent hydrogen or a straight, branched or cyclic alkyl group of 1 to 15 carbon atoms. Alternatively, R⁰⁰⁵ to R⁰⁰⁸, taken together, may form a ring, and in that event, at least one of R⁰⁰⁵ to R⁰⁰⁸ is a divalent hydrocarbon group of 1 to 15 carbon atoms having a carboxyl or hydroxyl group, while the remaining R's are independently single bonds or straight, branched or cyclic alkylene groups of 1 to 15 carbon atoms. R⁰⁰⁹ is a monovalent hydrocarbon group of 3 to 15 carbon atoms containing a —CO₂— partial structure. At least one of R⁰¹⁰ to R⁰¹³ is a monovalent hydrocarbon group of 2 to 15 carbon atoms containing a —CO₂— partial structure, while the remaining R's are independently hydrogen or straight, branched or cyclic alkyl groups of 1 to 15 carbon atoms. R⁰¹⁰ to R⁰¹³, taken together, may form a ring, and in that event, at least one of R⁰¹⁰ to R⁰¹³ is a divalent hydrocarbon group of 1 to 15 carbon atoms containing a —CO₂— partial structure, while the remaining R's are independently single bonds or straight, branched or cyclic alkylene groups of 1 to 15 carbon atoms. R⁰¹⁴ is a polycyclic hydrocarbon group having 7 to 15 carbon atoms or an alkyl group containing a polycyclic hydrocarbon group. R⁰¹⁵ is an acid labile group. X is CH₂ or an oxygen atom. Letter k is equal to 0 or 1.

More illustratively, R⁰⁰³ is a straight, branched or cyclic alkyl group of 1 to 15 carbon atoms, for example, methyl, ethyl, propyl, isopropyl, n-butyl, sec-butyl, tert-butyl, tert-amyl, n-pentyl, n-hexyl, cyclopentyl, cyclohexyl, ethylcyclopentyl, butylcyclopentyl, ethylcyclohexyl, butyl-cyclohexyl, adamantyl, ethyladamantyl, and butyladamantyl.

R⁰⁰⁴ is hydrogen or a monovalent hydrocarbon group of 1 to 15 carbon atoms having a carboxyl or hydroxyl group, for example, hydrogen, carboxyethyl, carboxybutyl, carboxy-cyclopentyl, carboxycyclohexyl, carboxynorbornyl, carboxy-adamantyl, hydroxyethyl, hydroxybutyl, hydroxycyclopentyl, hydroxycyclohexyl, hydroxynorbornyl, and hydroxyadamantyl.

At least one of R⁰⁰⁵ to R⁰⁰⁸ represents a monovalent hydrocarbon group of 1 to 15 carbon atoms having a carboxyl or hydroxyl group while the remaining R's independently represent hydrogen or a straight, branched or cyclic alkyl group of 1 to 15 carbon atoms. Examples of the carboxyl or hydroxyl-bearing monovalent hydrocarbon group of 1 to 15 carbon atoms include carboxy, carboxymethyl, carboxyethyl, carboxybutyl, hydroxymethyl, hydroxyethyl, hydroxybutyl, 2-carboxyethoxycarbonyl, 4-carboxybutoxycarbonyl, 2-hydroxyethoxycarbonyl, 4-hydroxybutoxycarbonyl, carboxycyclopentyloxycarbonyl, carboxycyclohexyloxycarbonyl, carboxynorbornyloxycarbonyl, carboxyadamantyloxycarbonyl, hydroxycyclopentyloxycarbonyl, hydroxycyclohexyloxycarbonyl, hydroxynorbornyloxycarbonyl, and hydroxyadamantyloxycarbonyl. Examples of the straight, branched or cyclic alkyl group of 1 to 15 carbon atoms are the same as exemplified for R⁰⁰³.

Alternatively, R⁰⁰⁵ to R⁰⁰⁸, taken together, may form a ring, and in that event, at least one of R⁰⁰⁵ to R⁰⁰⁸ is a divalent hydrocarbon group of 1 to 15 carbon atoms having a carboxyl or hydroxyl group, while the remaining R's are independently single bonds or straight, branched or cyclic alkylene groups of 1 to 15 carbon atoms. Examples of the carboxyl or hydroxyl-bearing divalent hydrocarbon group of 1 to 15 carbon atoms include the groups exemplified as the carboxyl or hydroxyl-bearing monovalent hydrocarbon group, with one hydrogen atom eliminated therefrom. Examples of the straight, branched or cyclic alkylene groups of 1 to 15 carbon atoms include the groups exemplified for R⁰⁰³, with one hydrogen atom eliminated therefrom.

R⁰⁰⁹ is a monovalent hydrocarbon group of 3 to 15 carbon atoms containing a —CO₂— partial structure, for example, 2-oxooxolan-3-yl, 4,4-dimethyl-2-oxooxolan-3-yl, 4-methyl-2-oxooxan-4-yl, 2-oxo-1,3-dioxolan-4-ylmethyl, and 5-methyl-2-oxooxolan-5-yl.

At least one of R⁰¹⁰ to R⁰¹³ is a monovalent hydrocarbon group of 2 to 15 carbon atoms containing a —CO₂— partial structure, while the remaining R's are independently hydrogen or straight, branched or cyclic alkyl groups of 1 to 15 carbon atoms. Examples of the monovalent hydrocarbon group of 2 to 15 carbon atoms containing a —CO₂— partial structure include 2-oxooxolan-3-yloxycarbonyl, 4,4-dimethyl-2-oxooxolan-3-yloxycarbonyl, 4-methyl-2-oxooxan-4-yloxycarbonyl, 2-oxo-1,3-dioxolan-4-ylmethyloxycarbonyl, and 5-methyl-2-oxooxolan-5-yloxycarbonyl. Examples of the straight, branched or cyclic alkyl groups of 1 to 15 carbon atoms are the same as exemplified for R⁰⁰³.

R⁰¹⁰ to R⁰¹³, taken together, may form a ring, and in that event, at least one of R⁰¹⁰ to R⁰¹³ is a divalent hydrocarbon group of 1 to 15 carbon atoms containing a —CO₂— partial structure, while the remaining R's are independently single bonds or straight, branched or cyclic alkylene groups of 1 to 15 carbon atoms. Examples of the divalent hydrocarbon group of 1 to 15 carbon atoms containing a —CO₂— partial structure include 1-oxo-2-oxapropane-1,3-diyl, 1,3-dioxo-2-oxapropane-1,3-diyl, 1-oxo-2-oxabutane-1,4-diyl, and 1,3-dioxo-2-oxabutane-1,4-diyl, as well as the groups exemplified as the monovalent hydrocarbon group of 1 to 15 carbon atoms containing a —CO₂— partial structure, with one hydrogen atom eliminated therefrom. Examples of the straight, branched or cyclic alkylene groups of 1 to 15 carbon atoms include the groups exemplified for R⁰⁰³, with one hydrogen atom eliminated therefrom.

R⁰¹⁴ is a polycyclic hydrocarbon group having 7 to 15 carbon atoms or an alkyl group containing a polycyclic hydrocarbon group, for example, norbornyl, bicyclo[3.3.1]-nonyl, tricyclo[5.2.1.0^{2,6}]decyl, adamantyl, ethyladamantyl, butyladamantyl, norbornylmethyl, and adamantylmethyl.

R⁰¹⁵ is an acid labile group, examples of which are the same as described above. X is CH₂ or an oxygen atom. Letter k is equal to 0 or 1.

The recurring units of formulae (M1) to (M8) are effective for imparting such desired properties as developer affinity, substrate adhesion and etching resistance to a resist composition based on a polymer comprising these recurring units. By adjusting the content of these recurring units, the performance of the resist composition can be finely adjusted.

The polymers of the invention have a weight average molecular weight of about 1,000 to 500,000, preferably about 3,000 to 100,000, as measured by gel permeation chromatography (GPC) using a polystyrene standard. Outside the range, the etching resistance may become extremely low and the resolution may become low because a substantial difference in rate of dissolution before and after exposure is lost.

The polymer of the invention can be prepared through copolymerization reaction using a compound of the following general formula (1a) as a first monomer, a compound of the following general formula (2a) as a second monomer, a compound(s) of the following general formula (3a) and/or (4a) as another essential monomer(s), and optionally, one or more members selected from compounds of the following general formulae (M1a) to (M8a) as subsequent monomers.

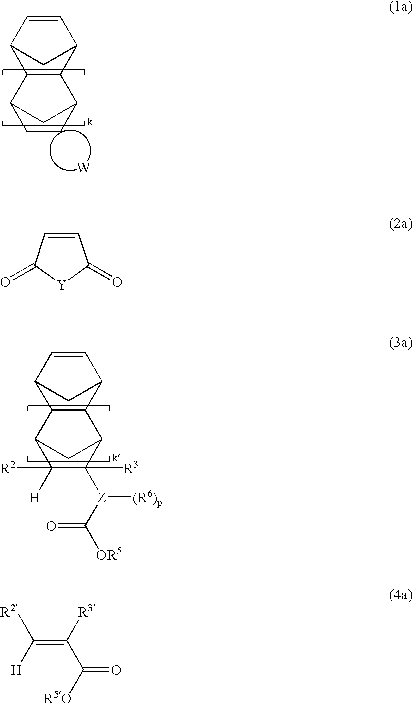

Herein, k, k′, p, R² to R⁶, R^{2′} to R^{5′}, W, Y and Z are as defined above.

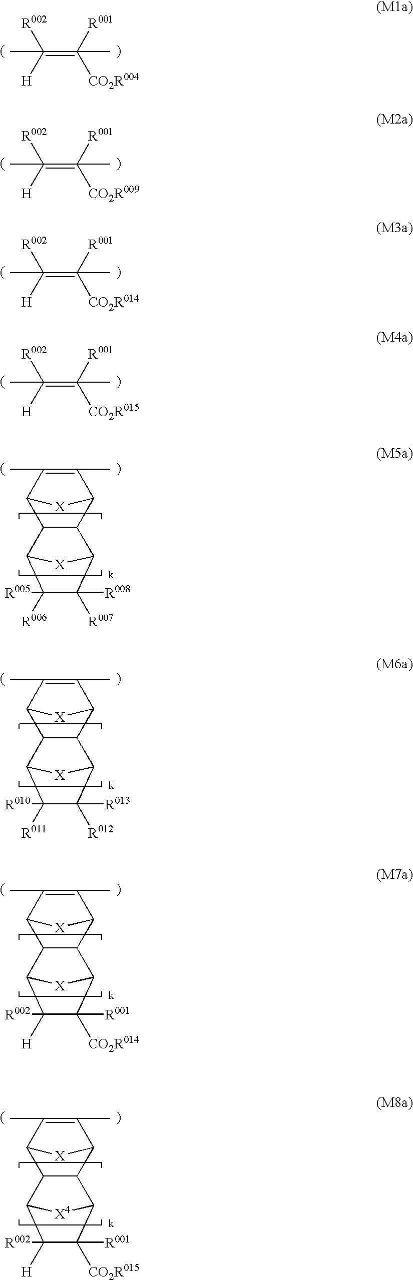

Herein, k, R⁰⁰¹ to R⁰¹⁵, and X are as defined above.

By properly adjusting the proportion of the respective monomers used in the copolymerization reaction, the polymer can be tailored so that it may exert the preferred performance when blended in resist compositions.

In addition to (i) the monomer of formula (1a), (ii) the monomer of formula (2a), (iii) the monomer or monomers of formulas (3a) and/or (4a), and (iv) the monomer or monomers of formulae (M1a) to (M8a), the polymer of the invention may have copolymerized therewith (v) another monomer having a carbon-to-carbon double bond other than (i) to (iv). Examples of the additional monomer (v) include substituted acrylic acid esters such as methyl methacrylate, methyl crotonate, dimethyl maleate, and dimethyl itaconate, unsaturated carboxylic acids such as maleic acid, fumaric acid and itaconic acid, substituted or unsubstituted norbornenes such as norbornene and methyl norbornene-5-carboxylate, and unsaturated acid anhydrides such as itaconic anhydride.

In the polymers of the invention, the preferred proportion of recurring units based on the respective monomers is in the following range (in mol %), though not limited thereto.

(I) When the polymer is comprised of recurring units of formula (1), recurring units of formula (2) and recurring units of formula (3), it contains

(i) 1 to 49%, preferably 3 to 45%, and more preferably 5 to 40% of recurring units of formula (1) based on the monomer of formula (1a),

(ii) 50% of recurring units of formula (2) based on the monomer of formula (2a),

(iii) 1 to 49%, preferably 3 to 45%, and more preferably 5 to 40% of recurring units of formula (3) based on the monomer of formula (3a),

(iv) 0 to 25%, preferably 0 to 20%, and more preferably 0 to 15% of recurring units of formulae (M5) to (M8) based on the monomers of formulae (M5a) to (M8a), and

(v) 0 to 25%, preferably 0 to 20%, and more preferably 0 to 15% of recurring units based on another monomer.

(II) When the polymer is comprised of recurring units of formula (1), recurring units of formula (2) and recurring units of formula (4), it contains

(i) 1 to 49%, preferably 3 to 45%, and more preferably 5 to 40% of recurring units of formula (1) based on the monomer of formula (1a),

(ii) 1 to 49%, preferably 5 to 45%, and more preferably 10 to 40% of recurring units of formula (2) based on the monomer of formula (2a),

(iii) 1 to 80%, preferably 1 to 70%, and more preferably 1 to 50% of recurring units of formula (4) based on the monomer of formula (4a),

(iv) 0 to 25%, preferably 0 to 20%, and more preferably 0 to 15% of recurring units of formulae (M1) to (M8) based on the monomers of formulae (M1a) to (M8a), and

(v) 0 to 25%, preferably 0 to 20%, and more preferably 0 to 15% of recurring units based on another monomer.

(III) When the polymer is comprised of recurring units of formula (1), recurring units of formula (2), recurring units of formula (3) and recurring units of formula (4), it contains

(i) 1 to 49%, preferably 3 to 45%, and more preferably 5 to 40% of recurring units of formula (1) based on the monomer of formula (1a),

(ii) 1 to 49%, preferably 5 to 45%, and more preferably 10 to 40% of recurring units of formula (2) based on the monomer of formula (2a),

(iii) 1 to 49%, preferably 3 to 45%, and more preferably 5 to 40% of recurring units of formula (3) based on the monomer of formula (3a),

(iv) 1 to 80%, preferably 1 to 70%, and more preferably 1 to 50% of recurring units of formula (4) based on the monomer of formula (4a),

(v) 0 to 25%, preferably 0 to 20%, and more preferably 0 to 15% of recurring units of formulae (M1) to (M8) based on the monomers of formulae (M1a) to (M8a), and

(vi) 0 to 25%, preferably 0 to 20%, and more preferably 0 to 15% of recurring units based on another monomer.

The monomers having a spiro ring of formula (1a) from which the units of formula (1) characteristic of the inventive polymer are derived can be prepared by various organic chemistry processes. One exemplary process involves effecting Diels-Alder reaction of a cyclic compound having a CH₂=partial structure directly attached thereto from without the ring such as itaconic anhydride with cyclopentadiene to form a basic skeleton, followed by conversion of functional groups to produce desired compounds. Another exemplary process involves effecting Diels-Alder reaction of an acyclic compound having a CH₂=partial structure directly attached to a non-terminal portion of its carbon chain such as itaconic ester with cyclopentadiene to synthesize a bicyclo[2.2.1]hept-2-ene compound having two substituents at 5-position or a tetracyclo[4.4.0.1^{2,5}.1^{7,10}]dodec-3-ene compound having two substituents at 8-position, followed by cyclization reaction of the two substituents to produce desired compounds. Useful processes are not limited to these.

The monomers having an acid labile group of formula (3a) can be prepared by the processes described in JP-A 2000-186118, JP-A 2000-309611, Japanese Patent Application No. 11-302948, Japanese Patent Application Nos. 2000-119410, 2000-127532, 2000-131164 and 2000-131177. They can also be prepared by modifying commercially available products and known materials by well-known organic chemistry formulations. The monomers having an acid labile group of formula (4a) can be prepared by the processes described in JP-A 2000-336121 and Japanese Patent Application No. 2001-115209 and also be prepared by modifying commercially available products and known materials by well-known organic chemistry formulations.

A variety of copolymerization reaction methods may be used for the preparation of the polymer according to the invention. The preferred polymerization reaction is radical polymerization.

For radical polymerization, preferred reaction conditions include (a) a solvent selected from among hydrocarbons such as benzene, ethers such as tetrahydrofuran, alcohols such as ethanol, and ketones such as methyl isobutyl ketone, (b) a polymerization initiator selected from azo compounds such as 2,2′-azobisisobutyronitrile and peroxides such as benzoyl peroxide and lauroyl peroxide, (c) a temperature of about 0° C. to about 100° C., and (d) a time of about ½ hour to about 48 hours. Reaction conditions outside the described range may be employed if desired.

### Resist Composition

Since the polymer of the invention is useful as the base resin of a resist composition, the other aspect of the invention provides a resist composition, especially a chemically amplified positive resist composition, comprising the polymer. Typically, the resist composition contains the polymer, a photoacid generator, and an organic solvent, and other optional components.

### Photoacid Generator

The photoacid generator is a compound capable of generating an acid upon exposure to high energy radiation or electron beams and includes the following:

(i) onium salts of the formula (P1a-1), (P1a-2) or (P1b),

(ii) diazomethane derivatives of the formula (P2),

(iii) glyoxime derivatives of the formula (P3),

(iv) bissulfone derivatives of the formula (P4),

(v) sulfonic acid esters of N-hydroxyimide compounds of the formula (P5),

(vi) β-ketosulfonic acid derivatives,

(vii) disulfone derivatives,

(viii) nitrobenzylsulfonate derivatives, and

(ix) sulfonate derivatives.

These photoacid generators are described in detail.

(i) Onium Salts of Formula (P1a-1), (P1a-2) or (P1b):

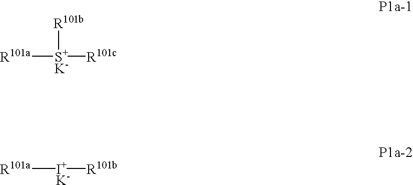

Herein, R^{101a}, R^{101b}, and R^{101c} independently represent straight, branched or cyclic alkyl, alkenyl, oxoalkyl or oxoalkenyl groups of 1 to 12 carbon atoms, aryl groups of 6 to 20 carbon atoms, or aralkyl or aryloxoalkyl groups of 7 to 12 carbon atoms, wherein some or all of the hydrogen atoms may be replaced by alkoxy or other groups. Also, R^{101b} and R^{101c}, taken together, may form a ring. R^{101b} and R^{101c} each are alkylene groups of 1 to 6 carbon atoms when they form a ring. K⁻ is a non-nucleophilic counter ion.

R^{101a}, R^{101b}, and R^{101c} may be the same or different and are illustrated below. Exemplary alkyl groups include methyl, ethyl, propyl, isopropyl, n-butyl, sec-butyl, tert-butyl, pentyl, hexyl, heptyl, octyl, cyclopentyl, cyclohexyl, cycloheptyl, cyclopropylmethyl, 4-methylcyclo-hexyl, cyclohexylmethyl, norbornyl, and adamantyl. Exemplary alkenyl groups include vinyl, allyl, propenyl, butenyl, hexenyl, and cyclohexenyl. Exemplary oxoalkyl groups include 2-oxocyclopentyl and 2-oxocyclohexyl as well as 2-oxopropyl, 2-cyclopentyl-2-oxoethyl, 2-cyclohexyl-2-oxoethyl, and 2-(4-methylcyclohexyl)-2-oxoethyl. Exemplary aryl groups include phenyl and naphthyl; alkoxyphenyl groups such as p-methoxyphenyl, m-methoxyphenyl, o-methoxyphenyl, ethoxyphenyl, p-tert-butoxyphenyl, and m-tert-butoxyphenyl; alkylphenyl groups such as 2-methylphenyl, 3-methylphenyl, 4-methylphenyl, ethylphenyl, 4-tert-butylphenyl, 4-butylphenyl, and dimethylphenyl; alkylnaphthyl groups such as methylnaphthyl and ethylnaphthyl; alkoxynaphthyl groups such as methoxynaphthyl and ethoxynaphthyl; dialkylnaphthyl groups such as dimethylnaphthyl and diethylnaphthyl; and dialkoxynaphthyl groups such as dimethoxynaphthyl and diethoxynaphthyl. Exemplary aralkyl groups include benzyl, phenylethyl, and phenethyl. Exemplary aryloxoalkyl groups are 2-aryl-2-oxoethyl groups such as 2-phenyl-2-oxoethyl, 2-(1-naphthyl)-2-oxoethyl, and 2-(2-naphthyl)-2-oxoethyl. Examples of the non-nucleophilic counter ion represented by K⁻ include halide ions such as chloride and bromide ions, fluoroalkylsulfonate ions such as triflate, 1,1,1-trifluoroethanesulfonate, and nonafluorobutanesulfonate, arylsulfonate ions such as tosylate, benzenesulfonate, 4-fluorobenzenesulfonate, and 1,2,3,4,5-pentafluorobenzenesulfonate, and alkylsulfonate ions such as mesylate and butanesulfonate.

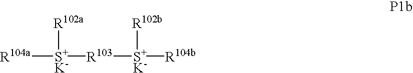

Herein, R^{102a} and R^{102b} independently represent straight, branched or cyclic alkyl groups of 1 to 8 carbon atoms. R¹⁰³ represents a straight, branched or cyclic alkylene groups of 1 to 10 carbon atoms. R^{104a} and R^{104b} independently represent 2-oxoalkyl groups of 3 to 7 carbon atoms. K⁻ is a non-nucleophilic counter ion.

Illustrative of the groups represented by R^{102a} and R^{102b} are methyl, ethyl, propyl, isopropyl, n-butyl, sec-butyl, tert-butyl, pentyl, hexyl, heptyl, octyl, cyclopentyl, cyclohexyl, cyclopropylmethyl, 4-methylcyclohexyl, and cyclohexylmethyl. Illustrative of the groups represented by R¹⁰³ are methylene, ethylene, propylene, butylene, pentylene, hexylene, heptylene, octylene, nonylene, 1,4-cyclohexylene, 1,2-cyclohexylene, 1,3-cyclopentylene, 1,4-cyclooctylene, and 1,4-cyclohexanedimethylene. Illustrative of the groups represented by R^{104a} and R^{104b} are 2-oxopropyl, 2-oxocyclopentyl, 2-oxocyclohexyl, and 2-oxocycloheptyl. Illustrative examples of the counter ion represented by K⁻ are the same as exemplified for formulae (P1a-1) and (P1a-2).

(ii) Diazomethane Derivatives of Formula (P2)

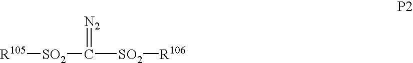

Herein, R¹⁰⁵ and R¹⁰⁶ independently represent straight, branched or cyclic alkyl or halogenated alkyl groups of 1 to 12 carbon atoms, aryl or halogenated aryl groups of 6 to 20 carbon atoms, or aralkyl groups of 7 to 12 carbon atoms.

Of the groups represented by R¹⁰⁵ and R¹⁰⁶, exemplary alkyl groups include methyl, ethyl, propyl, isopropyl, n-butyl, sec-butyl, tert-butyl, pentyl, hexyl, heptyl, octyl, amyl, cyclopentyl, cyclohexyl, cycloheptyl, norbornyl, and adamantyl. Exemplary halogenated alkyl groups include trifluoromethyl, 1,1,1-trifluoroethyl, 1,1,1-trichloroethyl, and nonafluorobutyl. Exemplary aryl groups include phenyl; alkoxyphenyl groups such as p-methoxyphenyl, m-methoxyphenyl, o-methoxyphenyl, ethoxyphenyl, p-tert-butoxyphenyl, and m-tert-butoxyphenyl; and alkylphenyl groups such as 2-methylphenyl, 3-methylphenyl, 4-methylphenyl, ethylphenyl, 4-tert-butylphenyl, 4-butylphenyl, and dimethylphenyl. Exemplary halogenated aryl groups include fluorophenyl, chlorophenyl, and 1,2,3,4,5-pentafluorophenyl. Exemplary aralkyl groups include benzyl and phenethyl.

(iii) Glyoxime Derivatives of Formula (P3)

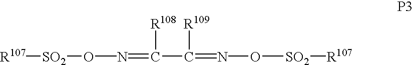

Herein, R¹⁰⁷, R¹⁰⁸, and R¹⁰⁹ independently represent straight, branched or cyclic alkyl or halogenated alkyl groups of 1 to 12 carbon atoms, aryl or halogenated aryl groups of 6 to 20 carbon atoms, or aralkyl groups of 7 to 12 carbon atoms. Also, R¹⁰⁸ and R¹⁰⁹, taken together, may form a ring. R¹⁰⁸ and R¹⁰⁹ each are straight or branched alkylene groups of 1 to 6 carbon atoms when they form a ring.

Illustrative examples of the alkyl, halogenated alkyl, aryl, halogenated aryl, and aralkyl groups represented by R¹⁰⁷ , R¹⁰⁸, and R¹⁰⁹ are the same as exemplified for R¹⁰⁵ and R¹⁰⁶. Examples of the alkylene groups represented by R¹⁰⁸ and R¹⁰⁹ include methylene, ethylene, propylene, butylene, and hexylene.

(iv) Bissulfone Derivatives of Formula (P4)

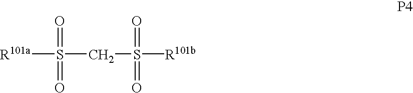

Herein, R^{101a} and R^{101b} are as defined above.

(v) Sulfonic Acid Esters of N-Hydroxyimide Compounds of Formula (P5)

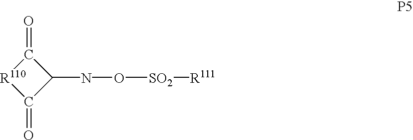

Herein, R¹¹⁰ is an arylene group of 6 to 10 carbon atoms, alkylene group of 1 to 6 carbon atoms, or alkenylene group of 2 to 6 carbon atoms wherein some or all of the hydrogen atoms may be replaced by straight or branched alkyl or alkoxy groups of 1 to 4 carbon atoms, nitro, acetyl, or phenyl groups. R¹¹¹ is a straight, branched or cyclic alkyl group of 1 to 8 carbon atoms, alkenyl, alkoxyalkyl, phenyl or naphthyl group wherein some or all of the hydrogen atoms may be replaced by alkyl or alkoxy groups of 1 to 4 carbon atoms, phenyl groups (which may have substituted thereon an alkyl or alkoxy of 1 to 4 carbon atoms, nitro, or acetyl group), hetero-aromatic groups of 3 to 5 carbon atoms, or chlorine or fluorine atoms.

Of the groups represented by R¹¹⁰, exemplary arylene groups include 1,2-phenylene and 1,8-naphthylene; exemplary alkylene groups include methylene, ethylene, trimethylene, tetramethylene, phenylethylene, and norbornane-2,3-diyl; and exemplary alkenylene groups include 1,2-vinylene, 1-phenyl-1,2-vinylene, and 5-norbornene-2,3-diyl. Of the groups represented by R¹¹¹, exemplary alkyl groups are as exemplified for R^{101a} to R^{101c}; exemplary alkenyl groups include vinyl, 1-propenyl, allyl, 1-butenyl, 3-butenyl, isoprenyl, 1-pentenyl, 3-pentenyl, 4-pentenyl, dimethylallyl, 1-hexenyl, 3-hexenyl, 5-hexenyl, 1-heptenyl, 3-heptenyl, 6-heptenyl, and 7-octenyl; and exemplary alkoxyalkyl groups include methoxymethyl, ethoxymethyl, propoxymethyl, butoxymethyl, pentyloxymethyl, hexyloxymethyl, heptyloxy-methyl, methoxyethyl, ethoxyethyl, propoxyethyl, butoxyethyl, pentyloxyethyl, hexyloxyethyl, methoxypropyl, ethoxypropyl, propoxypropyl, butoxypropyl, methoxybutyl, ethoxybutyl, propoxybutyl, methoxypentyl, ethoxypentyl, methoxyhexyl, and methoxyheptyl.

Of the substituents on these groups, the alkyl groups of 1 to 4 carbon atoms include methyl, ethyl, propyl, isopropyl, n-butyl, isobutyl and tert-butyl; the alkoxy groups of 1 to 4 carbon atoms include methoxy, ethoxy, propoxy, isopropoxy, n-butoxy, isobutoxy, and tert-butoxy; the phenyl groups which may have substituted thereon an alkyl or alkoxy of 1 to 4 carbon atoms, nitro, or acetyl group include phenyl, tolyl, p-tert-butoxyphenyl, p-acetylphenyl and p-nitrophenyl; the hetero-aromatic groups of 3 to 5 carbon atoms include pyridyl and furyl.

Illustrative examples of the photoacid generator include:

onium salts such as diphenyliodonium trifluoromethanesulfonate, (p-tert-butoxyphenyl)phenyliodonium trifluoromethanesulfonate, diphenyliodonium p-toluenesulfonate, (p-tert-butoxyphenyl)phenyliodonium p-toluenesulfonate, triphenylsulfonium trifluoromethanesulfonate, (p-tert-butoxyphenyl)diphenylsufonium trifluoromethanesulfonate, bis(p-tert-butoxyphenyl)phenylsulfonium trifluoromethanesulfonate, tris(p-tert-butoxyphenyl)sulfonium trifluoromethanesulfonate, triphenylsulfonium p-toluenesulfonate, (p-tert-butoxyphenyl)diphenylsulfonium p-toluenesulfonate, bis(p-tert-butoxyphenyl)phenylsulfonium p-toluenesulfonate, tris(p-tert-butoxyphenyl)sulfonium p-toluenesulfonate, triphenylsulfonium nonafluorobutanesulfonate, triphenylsulfonium butanesulfonate, trimethylsulfonium trifluoro-methanesulfonate, trimethylsulfonium p-toluenesulfonate, cyclohexylmethyl(2-oxocyclohexyl)sulfonium trifluoromethanesulfonate, cyclohexylmethyl(2-oxocyclohexyl)sulfonium p-toluenesulfonate, dimethylphenylsulfonium trifluoromethanesulfonate, dimethylphenylsulfonium p-toluenesulfonate, dicyclohexylphenylsulfonium trifluoromethanesulfonate, dicyclohexylphenylsulfonium p-toluenesulfonate, trinaphthylsulfonium trifluoromethanesulfonate, cyclohexylmethyl(2-oxyocyclohexyl)sulfonium trifluoromethanesulfonate, (2-norbornyl)methyl(2-oxocyclohexyl)sulfonium trifluoromethanesulfonate, ethylenebis[methyl(2-oxocyclopentyl)-sulfonium trifluoromethanesulfonate], and 1,2′-naphthyl-carbonylmethyltetrahdrothiophenium triflate;

diazomethane derivatives such as bis(benzenesulfonyl)-diazomethane, bis(p-toluenesulfonyl)diazomethane, bis(xylenesulfonyl)diazomethane, bis(cyclohexylsulfonyl)-diazomethane, bis(cyclopentylsulfonyl)diazomethane, bis(n-butylsulfonyl)diazomethane, bis(isobutylsulfonyl)-diazomethane, bis(sec-butylsulfonyl)diazomethane, bis(n-propylsulfonyl)diazomethane, bis(isopropylsulfonyl)-diazomethane, bis(tert-butylsulfonyl)diazomethane, bis(n-amylsulfonyl)diazomethane, bis(isoamylsulfonyl)-diazomethane, bis(sec-amylsulfonyl)diazomethane, bis(tert-amylsulfonyl)diazomethane, 1-cyclohexylsulfonyl-1-(tert-butylsulfonyl)diazomethane, 1-cyclohexylsulfonyl-1-(tert-anylsulfonyl)diazomethane, and 1-tert-amylsulfonyl-1-(tert-butylsulfonyl)diazomethane;

glyoxime derivatives such as bis-O-(p-toluene-sulfonyl)-α-dimethylglyoxime, bis-O-(p-toluenesulfonyl)-α-dipheylglyoxime, bis-O-(p-toluenesulfonyl)-α-dicyclohexyl-glyoxime, bis-O-(p-toluenesulfonyl)-2,3-pentanedioneglyoxime, bis-O-(p-toluenesulfonyl)-2-methyl-3,4-pentanedioneglyoxime, bis-O-(n-butanesulfonyl)-α-dimethylglyoxime, bis-O-(n-butanesulfonyl)-α-diphenylglyoxime, bis-O-(n-butanesulfonyl)-α-dicyclohexylglyoxime, bis-O-(n-butanesulfonyl)-2,3-pentanedioneglyoxime, bis-O-(n-butanesulfonyl)-2-methyl-3,4-pentanedioneglyoxime, bis-O-(methanesulfonyl)-α-dimethylglyoxime, bis-O-(trifluoromethanesulfonyl)-α-dimethylglyoxime, bis-O-(1,1,1-trifluoroethanesulfonyl)-α-dimethylglyoxime, bis-O-(tert-butanesulfonyl)-α-dimethylglyoxime, bis-O-(perfluorooctanesulfonyl)-α-dimethylglyoxime, bis-O-(cyclohexanesulfonyl)-α-dimethylglyoxime, bis-O-(benzenesulfonyl)-α-dimethylglyoxime, bis-O-(p-fluorobenzenesulfonyl)-α-dimethylglyoxime, bis-O-(p-tert-butylbenzenesulfonyl)-α-dimethylglyoxime, bis-O-(xylenesulfonyl)-α-dimethylglyoxime, and bis-O-(camphorsulfonyl)-α-dimethylglyoxime;

bissulfone derivatives such as bisnaphthylsulfonyl-methane, bistrifluoromethylsulfonylmethane, bismethyl-sulfonylmethane, bisethylsulfonylmethane, bispropylsulfonyl-methane, bisisopropylsulfonylmethane, bis-p-toluenesulfonyl-methane, and bisbenzenesulfonylmethane;

β-ketosulfone derivatives such as 2-cyclohexyl-carbonyl-2-(p-toluenesulfonyl)propane and 2-isopropyl-caronyl-2-(p-toluenesulfonyl)propane;

disulfone derivatives such as diphenyl disulfone and dicyclohexyl disulfone;

nitrobenzyl sulfonate derivatives such as 2,6-dinitrobenzyl p-toluenesulfonate and 2,4-dinitrobenzyl p-toluenesulfonate;

sulfonic acid ester derivatives such as 1,2,3-tris-(methanesulfonyloxy)benzene, 1,2,3-tris(trifluoromethane-sulfonyloxy)benzene, and 1,2,3-tris(p-toluenesulfonyloxy)-benzene; and

sulfonic acid esters of N-hydroxyimides such as N-hydroxysuccinimide methanesulfonate, N-hydroxysuccinimide trifluoromethanesulfonate, N-hydroxysuccinimide ethanesulfonate, N-hydroxysuccinimide 1-propanesulfonate, N-hydroxysuccinimide 2-propanesulfonate, N-hydroxysuccinimide 1-pentanesulfonate, N-hydroxysuccinimide 1-octanesulfonate, N-hydroxysuccinimide p-toluenesulfonate, N-hydroxysuccinimide p-methoxybenzenesulfonate, N-hydroxysuccinimide 2-chloroethanesulfonate, N-hydroxysuccinimide benzenesulfonate, N-hydroxysuccinimide 2,4,6-trimethylbenzenesulfonate, N-hydroxysuccinimide 1-naphthalene-sulfonate, N-hydroxysuccinimide 2-naphthalenesulfonate, N-hydroxy-2-phenylsuccinimide methanesulfonate, N-hydroxymaleimide methanesulfonate, N-hydroxymaleimide ethane-sulfonate, N-hydroxy-2-phenylmaleimide methanesulfonate, N-hydroxyglutarimide methanesulfonate, N-hydroxyglutarimide benzenesulfonate, N-hydroxyphthalimide methanesulfonate, N-hydroxyphthalimide benzenesulfonate, N-hydroxyphthalimide trifluoromethanesulfonate, N-hydroxyphthalimide p-toluenesulfonate, N-hydroxynaphthalimide methanesulfonate, N-hydroxynaphthalimide benzenesulfonate, N-hydroxy-5-norbornene-2,3-dicarboxyimide methanesulfonate, N-hydroxy-5-norbornene-2,3-dicarboxyimide trifluoromethanesulfonate, and N-hydroxy-5-norbornene-2,3-dicarboxyimide p-toluenesulfonate.

Preferred among these photoacid generators are onium salts such as triphenylsulfonium trifluoromethanesulfonate, (p-tert-butoxyphenyl)diphenylsulfonium trifluoromethane-sulfonate, tris(p-tert-butoxyphenyl)sulfonium trifluoro-methanesulfonate, methanesulfonate, triphenylsulfonium p-toluenesulfonate, (p-tert-butoxyphenyl)diphenylsulfonium p-toluenesulfonate, tris(p-tert-butoxyphenyl)sulfonium p-toluenesulfonate, trinaphthylsulfonium trifluoromethanesulfonate, cyclohexyl-methyl(2-oxocyclohexyl)sulfonium trifluoromethanesulfonate, (2-norbornyl)methyl(2-oxocylohexyl)sulfonium trifluoro-methanesulfonate, and 1,2′-naphthylcarbonylmethyltetrahydro-thiophenium triflate; diazomethane derivatives such as bis(benzenesulfonyl)diazomethane, bis(p-toluenesulfonyl)-diazomethane, bis(cyclohexylsulfonyl)diazomethane, bis(n-butylsulfonyl)diazomethane, bis(isobutylsulfonyl)-diazomethane, bis(sec-butylsulfonyl)diazomethane, bis(n-propylsulfonyl)diazomethane, bis(isopropylsulfonyl)-diazomethane, and bis(tert-butylsulfonyl)diazomethane; glyoxime derivatives such as bis-O-(p-toluenesulfonyl)-α-dimethylglyoxime and bis-O-(n-butanesulfonyl)-α-dimethyl-glyoxime; bissulfone derivatives such as bisnaphthyl-sufonylmethane; and sulfonic acid esters of N-hydroxyimide compounds such as N-hydroxysuccinimide methanesulfonate, N-hydroxysuccinimide trifluoromethanesulfonate, N-hydroxy-succinimide 1-propanesulfonate, N-hydroxysuccinimide 2-propanesulfonate, N-hydroxysuccinimide 1-pentanesulfonate, N-hydroxysuccinimide p-toluenesulfonate, N-hydroxynaphthal-imide methanesulfonate, and N-hydroxynaphthalimide benzenesulfonate.

These photoacid generators may be used singly or in combinations of two or more thereof. Onium salts are effective for improving rectangularity, while diazomethane derivatives and glyoxime derivatives are effective for reducing standing waves. The combination of an onium salt with a diazomethane or a glyoxime derivative allows for fine adjustment of the profile.

The photoacid generator is added in an amount of 0.1 to 15 parts, and especially 0.5 to 8 parts by weight, per 100 parts by weight of the base resin (all parts are by weight, hereinafter). Less than 0.1 part of the photoacid generator would provide a poor sensitivity whereas more than 15 parts of the photoacid generator would adversely affect transparency and resolution.

### Organic Solvent

The organic solvent used herein may be any organic solvent in which the base resin, photoacid generator, and other components are soluble. Illustrative, non-limiting, examples of the organic solvent include ketones such as cyclohexanone and methyl-2-n-amylketone; alcohols such as 3-methoxybutanol, 3-methyl-3-methoxybutanol, 1-methoxy-2-propanol, and 1-ethoxy-2-propanol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; and esters such as propylene glycol monomethyl ether acetate, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate. These solvents may be used alone or in combinations of two or more thereof. Of the above organic solvents, it is recommended to use diethylene glycol dimethyl ether and 1-ethoxy-2-propanol because the photoacid generator is most soluble therein, propylene glycol monomethyl ether acetate because it is a safe solvent, or a mixture thereof.

An appropriate amount of the organic solvent used is about 200 to 1,000 parts, especially about 400 to 800 parts by weight per 100 parts by weight of the base resin.

### Other Polymer

To the resist composition of the invention, another polymer other than the inventive polymer comprising recurring units of formulae (1) and (2) may also be added. The other polymers that can be added to the resist composition are, for example, those polymers comprising units of the following formula (R1) and/or (R2) and having a weight average molecular weight of about 1,000 to about 500,000, especially about 5,000 to about 100,000 although the other polymers are not limited thereto.

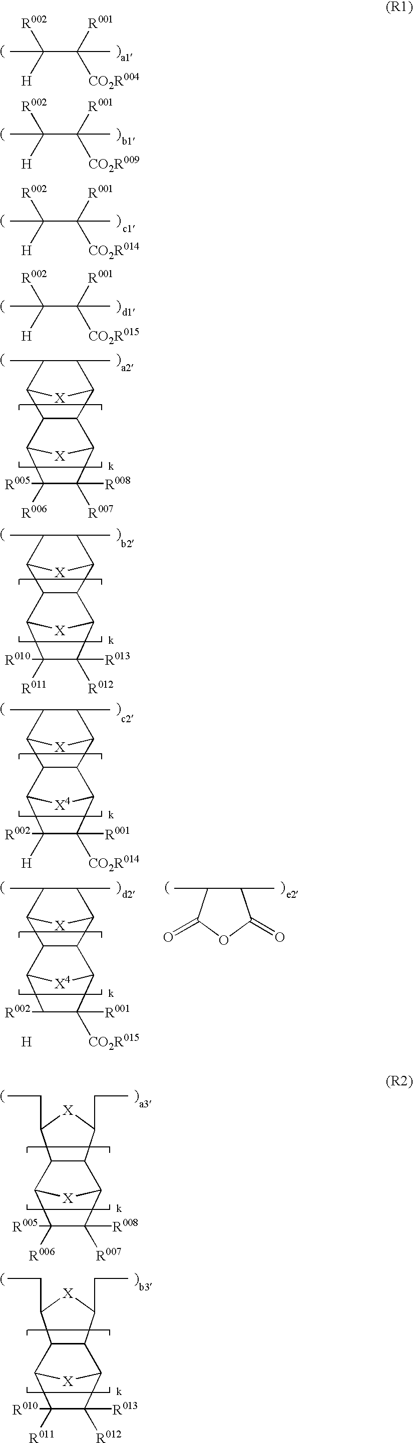

Herein, R⁰⁰¹ is hydrogen, methyl or CH₂CO₂R⁰⁰³. R⁰⁰² is hydrogen, methyl or CO₂R⁰⁰³. R⁰⁰³ is a straight, branched or cyclic alkyl group of 1 to 15 carbon atoms. R⁰⁰⁴ is hydrogen or a monovalent hydrocarbon group of 1 to 15 carbon atoms having a carboxyl or hydroxyl group. At least one of R⁰⁰⁵ to R⁰⁰⁸ represents a monovalent hydrocarbon group of 1 to 15 carbon atoms having a carboxyl or hydroxyl group while the remaining R's independently represent hydrogen or a straight, branched or cyclic alkyl group of 1 to 15 carbon atoms. Alternatively, R⁰⁰⁵ to R⁰⁰⁸ , taken together, may form a ring, and in that event, at least one of R⁰⁰⁵ to R⁰⁰⁸ is a divalent hydrocarbon group of 1 to 15 carbon atoms having a carboxyl or hydroxyl group, while the remaining R's are independently single bonds or straight, branched or cyclic alkylene groups of 1 to 15 carbon atoms. R⁰⁰⁹ is a monovalent hydrocarbon group of 3 to 15 carbon atoms containing a CO₂ partial structure. At least one of R⁰¹⁰ to R⁰¹³ is a monovalent hydrocarbon group of 2 to 15 carbon atoms containing a CO₂ partial structure, while the remaining R's are independently hydrogen or straight, branched or cyclic alkyl groups of 1 to 15 carbon atoms. R⁰¹⁰ to R⁰¹³, taken together, may form a ring, and in that event, at least one of R⁰¹⁰ to R⁰¹³ is a divalent hydrocarbon group of 1 to 15 carbon atoms containing a CO₂ partial structure, while the remaining R's are independently single bonds or straight, branched or cyclic alkylene groups of 1 to 15 carbon atoms. R⁰¹⁴ is a polycyclic hydrocarbon group having 7 to 15 carbon atoms or an alkyl group containing a polycyclic hydrocarbon group. R⁰¹⁵ is an acid labile group. R⁰¹⁶ is hydrogen or methyl. R⁰¹⁷ is a straight, branched or cyclic alkyl group of 1 to 8 carbon atoms. X is CH₂ or an oxygen atom. Letter k′ is equal to 0 or 1; a1′, a2′, a3′, b1′, b2′, b3′, c1′, c2′, c3′, d1′, d2′, d3′, and e′ are numbers from 0 to less than 1, satisfying a1′+a2′+a3′+b1′+b2′+b3′+c1′+c2′+c3′+d1′+d2′+d3′+e′=1; f′, g′, h′, i′, and j′ are numbers from 0 to less than 1, satisfying f′+g′+h′+i′+j′=1.

Exemplary groups of these R's are as exemplified above.

The inventive polymer (comprising recurring units of formulae (1) and (2)) and the other polymer are preferably blended in a weight ratio from 100:0 to 10:90, more preferably from 100:0 to 20:80. If the blend ratio of the inventive polymer is below this range, the resist composition would become poor in some of the desired properties. The properties of the resist composition can be adjusted by properly changing the blend ratio of the inventive polymer.

The other polymer is not limited to one type and a mixture of two or more other polymers may be added. The use of plural polymers allows for easy adjustment of resist properties.

### Dissolution Regulator

To the resist composition, a dissolution regulator may be added. The dissolution regulator is a compound having on the molecule at least two phenolic hydroxyl groups, in which an average of from 0 to 100 mol % of all the hydrogen atoms on the phenolic hydroxyl groups are replaced with acid labile groups or a compound having on the molecule at least one carboxyl group, in which an average of 50 to 100 mol % of all the hydrogen atoms on the carboxyl groups are replaced with acid labile groups, both the compounds having an average molecular weight within a range of 100 to 1,000, and preferably 150 to 800.

The degree of substitution of the hydrogen atoms on the phenolic hydroxyl groups with acid labile groups is on average at least 0 mol %, and preferably at least 30 mol %, of all the phenolic hydroxyl groups. The upper limit is 100 mol%, and preferably 80 mol %. The degree of substitution of the hydrogen atoms on the carboxyl groups with acid labile groups is on average at least 50 mol %, and preferably at least 70 mol %, of all the carboxyl groups, with the upper limit being 100 mol %.

Preferable examples of such compounds having two or more phenolic hydroxyl groups or compounds having at least one carboxyl group include those of formulas (D1) to (D14) below.

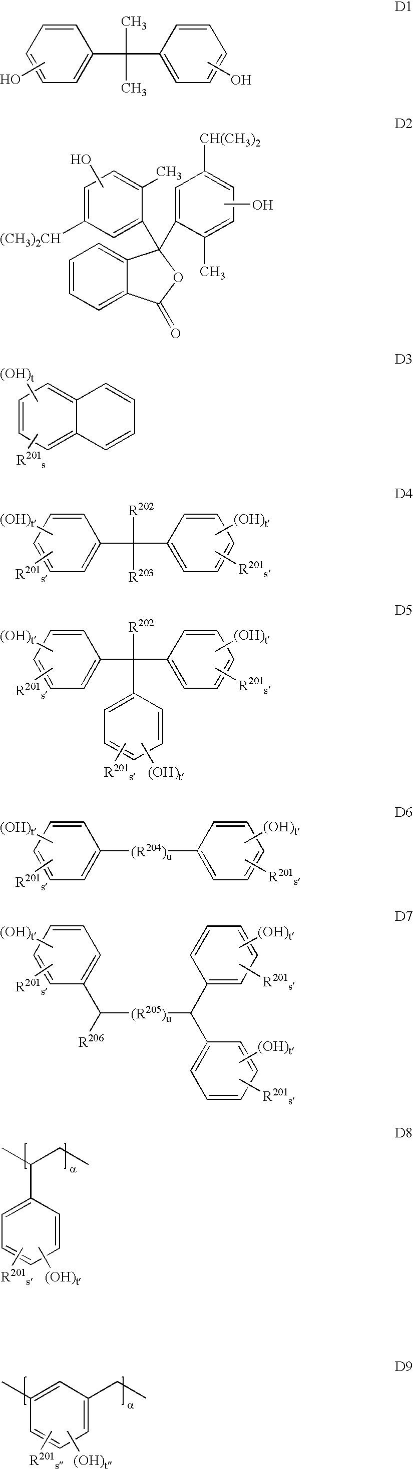

In these formulas, R²⁰¹ and R²⁰² are each hydrogen or a straight or branched alkyl or alkenyl of 1 to 8 carbon atoms; R²⁰³ is hydrogen, a straight or branched alkyl or alkenyl of 1 to 8 carbon atoms, or —(R²⁰⁷)ₕ—COOH; R²⁰⁴ is —(CH₂)ᵢ— (where i=2 to 10), an arylene of 6 to 10 carbon atoms, carbonyl, sulfonyl, an oxygen atom, or a sulfur atom; R²⁰⁵ is an alkylene of 1 to 10 carbon atoms, an arylene of 6 to 10 carbon atoms, carbonyl, sulfonyl, an oxygen atom, or a sulfur atom; R²⁰⁶ is hydrogen, a straight or branched alkyl or alkenyl of 1 to 8 carbon atoms, or a hydroxyl-substituted phenyl or naphthyl; R²⁰⁷ is a straight or branched alkylene of 1 to 10 carbon atoms; R²⁰⁸ is hydrogen or hydroxyl; the letter j is an integer from 0 to 5; u and h are each 0 or 1; s, t, s′, t′, s″, and t″ are each numbers which satisfy s+t=8, s′+t′=5, and s″+t″=4, and are such that each phenyl skeleton has at least one hydroxyl group; and a is a number such that the compounds of formula (D8) or (D9) have a molecular weight of from 100 to 1,000.

In the above formulas, suitable examples of R²⁰¹ and R²⁰² include hydrogen, methyl, ethyl, butyl, propyl, ethynyl, and cyclohexyl; suitable examples of R²⁰³ include the same groups as for R²⁰¹ and R²⁰² as well as —COOH and —CH₂COOH; suitable examples of R²⁰⁴ include ethylene, phenylene, carbonyl, sulfonyl, oxygen, and sulfur; suitable examples of R²⁰⁵ include methylene as well as the same groups as for R²⁰⁴; and suitable examples of R²⁰⁶ include hydrogen, methyl, ethyl, butyl, propyl, ethynyl, cyclohexyl, and hydroxyl-substituted phenyl or naphthyl.

Exemplary acid labile groups on the dissolution regulator include groups of the following general formulae (L1) to (L4), tertiary alkyl groups of 4 to 20 carbon atoms, trialkylsilyl groups in which each of the alkyls has 1 to 6 carbon atoms, and oxoalkyl groups of 4 to 20 carbon atoms.

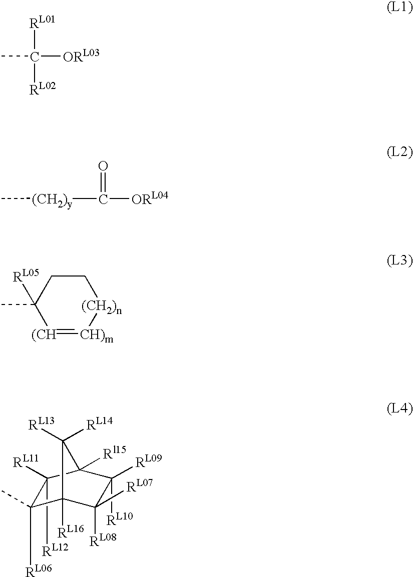

In these formulas, R^{L01} and R^{L02} are each hydrogen or a straight, branched or cyclic alkyl having 1 to 18 carbon atoms; and R^{L03} is a monovalent hydrocarbon group of 1 to 18 carbon atoms which may contain a heteroatom (e.g., oxygen). A pair of R^{L01} and R^{L02}, a pair of R^{L01} and R^{L03} or a pair of R^{L02} and R^{L03} may together form a ring, with the proviso that R^{L01}, R^{L02}, and R^{L03} are each a straight or branched alkylene of 1 to 18 carbon atoms when they form a ring. R^{L04} is a tertiary alkyl group of 4 to 20 carbon atoms, a trialkysilyl group in which each of the alkyls has 1 to 6 carbon atoms, an oxoalkyl group of 4 to 20 carbon atoms, or a group of the formula (L1). R^{L05} is a monovalent hydrocarbon group of 1 to 8 carbon atoms which may contain a hetero atom or a substituted or unsubstituted aryl group of 6 to 20 carbon atoms. R^{L06} is a monovalent hydrocarbon group of 1 to 8 carbon atoms which may contain a hetero atom or a substituted or unsubstituted aryl group of 6 to 20 carbon atoms. R^{L07} to R^{L16} independently represent hydrogen or monovalent hydrocarbon groups of 1 to 15 carbon atoms which may contain a hetero atom. Alternatively, R^{L07} to R^{L16}, taken together, may form a ring. Each of R^{L07} to R^{L16} represents a divalent C₁-C₁₅ hydrocarbon group which may contain a hetero atom, when they form a ring. Two of R^{L07} to R_{L16} which are attached to adjoining carbon atoms may bond together directly to form a double bond. Letter y is an integer of 0 to 6. Letter m is equal to 0 or 1, n is equal to 0, 1, 2 or 3, and 2m+n is equal to 2 or 3. Illustrative examples of these groups are as previously exemplified.

The dissolution regulator may be formulated in an amount of 0 to 50 parts, preferably 0 to 40 parts, and more preferably 0 to 30 parts, per 100 parts of the base resin, and may be used singly or as a mixture of two or more thereof. The use of more than 50 parts would lead to slimming of the patterned film, and thus a decline in resolution.

The dissolution regulator can be synthesized by introducing acid labile groups into a compound having phenolic hydroxyl or carboxyl groups in accordance with an organic chemical formulation.

### Basic Compound

In the resist composition of the invention, a basic compound may be blended. A suitable basic compound used herein is a compound capable of suppressing the rate of diffusion when the acid generated by the photoacid generator diffuses within the resist film. The inclusion of this type of basic compound holds down the rate of acid diffusion within the resist film, resulting in better resolution. In addition, it suppresses changes in sensitivity following exposure, thus reducing substrate and environment dependence, as well as improving the exposure latitude and the pattern profile.

Examples of basic compounds include primary, secondary, and tertiary aliphatic amines, mixed amines, aromatic amines, heterocyclic amines, carboxyl group-bearing nitrogenous compounds, sulfonyl group-bearing nitrogenous compounds, hydroxyl group-bearing nitrogenous compounds, hydroxyphenyl group-bearing nitrogenous compounds, alcoholic nitrogenous compounds, amide derivatives, and imide derivatives.

Examples of suitable primary aliphatic amines include ammonia, methylamine, ethylamine, n-propylamine, isopropyl-amine, n-butylamine, iso-butylamine, sec-butylamine, tert-butylamine, pentylamine, tert-amylamine, cyclopentyl-amine, hexylamine, cyclohexylamine, heptylamine, octylamine, nonylamine, decylamine, dodecylamine, cetylamine, methylene-diamine, ethylenediamine, and tetraethylenepentamine. Examples of suitable secondary aliphatic amines include dimethylamine, diethylamine, di-n-propylamine, di-iso-propylamine, di-n-butylamine, di-iso-butylamine, di-sec-butylamine, dipentylamine, dicyclopentylamine, dihexylamine, dicyclohexylamine, diheptylamine, dioctylamine, dinonylamine, didecylamine, didodecylamine, dicetylamine, N,N-dimethyl-methylenediamine, N,N-dimethylethylenediamine, and N,N-dimethyltetraethylenepentamine. Examples of suitable tertiary aliphatic amines include trimethylamine, triethylamine, tri-n-propylamine, tri-iso-propylamine, tri-n-butylamine, tri-iso-butylamine, tri-sec-butylamine, tripentylamine, tricyclopentylamine, trihexylamine, tricyclohexylamine, triheptylamine, trioctylamine, trinonylamine, tridecylamine, tridodecylamine, tricetylamine, N,N,N′,N′-tetramethylmethylenediamine, N,N,N′,N′-tetramethylethylenediamine, and N,N,N′,N′-tetramethyltetraethylenepentamine.

Examples of suitable mixed amines include dimethyl-ethylamine, methylethylpropylamine, benzylamine, phenethyl-amine, and benzyldimethylamine. Examples of suitable aromatic and heterocyclic amines include aniline derivatives (e.g., aniline, N-methylaniline, N-ethylaniline, N-propylaniline, N,N-dimethylaniline, 2-methylaniline, 3-methylaniline, 4-methylaniline, ethylaniline, propylaniline, trimethylaniline, 2-nitroaniline, 3-nitroaniline, 4-nitroaniline, 2,4-dinitroaniline, 2,6-dinitroaniline, 3,5-dinitroaniline, and N,N-dimethyl-toluidine), diphenyl(p-tolyl)amine, methyldiphenylamine, triphenylamine, phenylenediamine, naphthylamine, diamino-naphthalene, pyrrole derivatives (e.g., pyrrole, 2H-pyrrole, 1-methylpyrrole, 2,4-dimethylpyrrole, 2,5-dimethylpyrrole, and N-methylpyrrole), oxazole derivatives (e.g., oxazole and isooxazole), thiazole derivatives (e.g., thiazole and isothiazole), imidazole derivatives (e.g., imidazole, 4-methylimidazole, and 4-methyl-2-phenylimidazole), pyrazole derivatives, furazan derivatives, pyrroline derivatives (e.g., pyrroline and 2-methyl-1-pyrroline), pyrrolidine derivatives (e.g., pyrrolidine, N-methylpyrrolidine, pyrrolidinone, and N-methylpyrrolidone), imidazoline derivatives, imidazolidine derivatives, pyridine derivatives (e.g., pyridine, methylpyridine, ethylpyridine, propylpyridine, butylpyridine, 4-(1-butylpentyl)pyridine, dimethylpyridine, trimethylpyridine, triethylpyridine, phenylpyridine, 3-methyl-2-phenylpyridine, 4-tert-butylpyridine, diphenylpyridine, benzylpyridine, methoxypyridine, butoxypyridine, dimethoxypyridine, 1-methyl-2-pyridone, 4-pyrrolidinopyridine, 1-methyl-4-phenylpyridine, 2-(1-ethylpropyl)pyridine, aminopyridine, and dimethylaminopyridine), pyridazine derivatives, pyrimidine derivatives, pyrazine derivatives, pyrazoline derivatives, pyrazolidine derivatives, piperidine derivatives, piperazine derivatives, morpholine derivatives, indole derivatives, isoindole derivatives, 1H-indazole derivatives, indoline derivatives, quinoline derivatives (e.g., quinoline and 3-quinolinecarbonitrile), isoquinoline derivatives, cinnoline derivatives, quinazoline derivatives, quinoxaline derivatives, phthalazine derivatives, purine derivatives, pteridine derivatives, carbazole derivatives, phenanthridine derivatives, acridine derivatives, phenazine derivatives, 1,10-phenanthroline derivatives, adenine derivatives, adenosine derivatives, guanine derivatives, guanosine derivatives, uracil derivatives, and uridine derivatives.

Examples of suitable carboxyl group-bearing nitrogenous compounds include aminobenzoic acid, indolecarboxylic acid, and amino acid derivatives (e.g. nicotinic acid, alanine, alginine, aspartic acid, glutamic acid, glycine, histidine, isoleucine, glycylleucine, leucine, methionine, phenylalanine, threonine, lysine, 3-aminopyrazine-2-carboxylic acid, and methoxyalanine). Examples of suitable sulfonyl group-bearing nitrogenous compounds include 3-pyridinesulfonic acid and pyridinium p-toluenesulfonate. Examples of suitable hydroxyl group-bearing nitrogenous compounds, hydroxyphenyl group-bearing nitrogenous compounds, and alcoholic nitrogenous compounds include 2-hydroxypyridine, aminocresol, 2,4-quinolinediol, 3-indolemethanol hydrate, monoethanol-amine, diethanolamine, triethanolamine, N-ethyldiethanol-amine, N,N-diethylethanolamine, triisopropanolamine, 2,2′-iminodiethanol, 2-aminoethanol, 3-amino-1-propanol, 4-amino-1-butanol, 4-(2-hydroxyethyl)morpholine, 2-(2-hydroxyethyl)pyridine, 1-(2-hydroxyethyl)piperazine, 1-[2-(2-hydroxyethoxy)ethyl]piperazine, piperidine ethanol, 1-(2-hydroxyethyl)pyrrolidine, 1-(2-hydroxyethyl)-2-pyrrolidinone, 3-piperidino-1,2-propanediol, 3-pyrrolidino-1,2-propanediol, 8-hydroxyjulolidine, 3-quinuclidinol, 3-tropanol, 1-methyl-2-pyrrolidine ethanol, 1-aziridine ethanol, N-(2-hydroxyethyl)phthalimide, and N-(2-hydroxy-ethyl)isonicotinamide. Examples of suitable amide derivatives include formamide, N-methylformamide, N,N-dimethylformamide, acetamide, N-methylacetamide, N,N-dimethylacetamide, propionamide, and benzamide. Suitable imide derivatives include phthalimide, succinimide, and maleimide.

In addition, basic compounds of the following general formula (B1) may also be included alone or in admixture.

N(X)ₙ(Y)₃₋ₙ B1

In the formula, n is equal to 1, 2 or 3; Y is independently hydrogen or a straight, branched or cyclic alkyl group of 1 to 20 carbon atoms which may contain a hydroxyl group or ether; and X is independently selected from groups of the following general formulas (X1) to (X3), and two or three X's may bond together to form a ring.

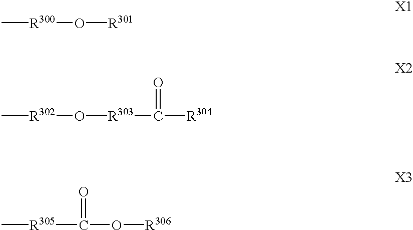

In the formulas, R³⁰⁰, R³⁰² and R³⁰⁵ are independently straight or branched alkylene groups of 1 to 4 carbon atoms; R³⁰¹, R³⁰⁴ and R³⁰⁶ are independently hydrogen, straight, branched or cyclic alkyl groups of 1 to 20 carbon atoms, which may contain at least one hydroxyl group, ether, ester or lactone ring; and R³⁰³ is a single bond or a straight or branched alkylene group of 1 to 4 carbon atoms.

Illustrative examples of the compounds of formula (B1) include tris(2-methoxymethoxyethyl)amine, tris{2-(2-methoxyethosy)ethyl}amine, tris{2-(2-methoxyethoxy-methoxy)ethyl}amine, tris{2-(1-methoxyethoxy)ethyl}amine, tris(2-(1-ethoxyethoxy)ethyl)amine, tris(2-(1-ethoxy-propoxy)ethyl}amine, tris[2-{2-(2-hydroxyethoxy)ethoxy)-ethyl]amine, 4,7,13,16,21,24-hexaoxa-1,10-diazabicyclo-[8.8.8]hexacosane, 4,7,13,18-tetraoxa-1,10-diazabicyclo-[8.5.5]eicosane, 1,4,10,13-tetraoxa-7,16-diazabicyclo-octadecane, 1-aza-12-crown-4, 1-aza-15-crown-5, 1-aza-18-crown-6, tris(2-formyloxyethyl)amine, tris(2-acetoxyethyl)-amine, tris(2-propionyloxyethyl)amine, tris(2-butyryloxy-ethyl)amine, tris(2-isobutyryloxyethyl)amine, tris(2-valeryloxyethyl)amine, tris(2-pivaloyloxyethyl)amine, N,N-bis(2-acetoxyethyl)-2-(acetoxyacetoxy)ethylamine, tris(2-methoxycarbonyloxyethyl)amine, tris(2-tert-butoxycarbonyloxyethyl)amine, tris[2-(2-oxopropoxy)ethyl]amine, tris[2-(methoxycarbonylmethyl)oxyethyl]amine, tris[2-(tert-butoxycarbonylmethyloxy)ethyl]amine, tris[2-(cyclohexyloxy-carbonylmethyloxy)ethyl]amine, tris(2-methoxycarbonylethyl)-amine, tris(2-ethoxycarbonylethyl)amine, N,N-bis(2-hydroxyethyl)-2-(methoxycarbonyl)ethylamine, N,N-bis(2-acetoxyethyl)-2-(methoxycarbonyl)ethylamine, N,N-bis(2-hydroxyethyl)-2-(ethoxycarbonyl)ethylamine, N,N-bis(2-acetoxyethyl)-2-(ethoxycarbonyl)ethylamine, N,N-bis(2-hydroxyethyl)-2-(2-methoxyethoxycarbonyl)ethylamine, N,N-bis(2-acetoxyethyl)-2-(2-methoxyethoxy-carbonyl)ethylamine, N,N-bis(2-hydroxyethyl)-2-(2-hydroxy-ethoxycarbonyl)ethylamine, N,N-bis(2-acetoxyethyl)-2-(2-acetoxyethoxycarbonyl)ethylamine, N,N-bis(2-hydroxyethyl)-2-[(methoxycarbonyl)methoxycarbonyl]ethylamine, N,N-bis(2-acetoxyethyl)-2-[(methoxycarbonyl)methoxycarbonyl]ethylamine, N,N-bis(2-hydroxyethyl)-2-(2-oxopropoxycarbonyl)ethylamine, N,N-bis(2-acetoxyethyl)-2-(2-oxopropoxycarbonyl)ethylamine, N,N-bis(2-hydroxyethyl)-2-(tetrahydrofurfuryloxycarbonyl)ethylamine, N,N-bis(2-acetoxyethyl)-2-(tetrahydrofurfuryloxycarbonyl)ethylamine, N,N-bis(2-hydroxyethyl)-2-[(2-oxotetrahydrofuran-3-yl)oxycarbonyl]ethylamine, N,N-bis(2-acetoxyethyl)-2-[(2-oxotetrahydrofuran-3-yl)oxycarbonyl]ethylamine, N,N-bis(2-hydroxy-ethyl)-2-(4-hydroxybutoxycarbonyl)ethylamine, N,N-bis(2-formyloxyethyl)-2-(4-formyloxybutoxycarbonyl)ethylamine, N,N-bis(2-formyloxyethyl)-2-(2-formyloxyethoxycarbonyl)-ethylamine, N,N-bis(2-methoxyethyl)-2-(methoxycarbonyl)-ethylamine, N-(2-hydroxyethyl)-bis[2-(methoxycarbonyl)-ethyl]amine, N-(2-acetoxyethyl)-bis[2-(methoxycarbonyl)-ethyl]amine, N-(2-hydroxyethyl)-bis[2-(ethoxycarbonyl)-ethyl]amine, N-(2-acetoxyethyl)-bis[2-(ethoxycarbonyl)-ethyl]amine, N-(3-hydroxy-l-propyl)-bis[2-(methoxycarbonyl)-ethylamine, N-(3-acetoxy--propyl) -bis[2-(methoxycarbonyl)-ethyl]amine, N-(2-methoxyethyl)-bis[2-(methoxycarbonyl)-ethyl]amine, N-butyl-bis[2-(methoxycarbonyl)ethyl]amine, N-butyl-bis[2-(2-methoxyethoxycarbonyl)ethyl]amine, N-methyl-bis(2-acetoxyethyl)amine, N-ethyl-bis(2-acetoxy-ethyl)amine, N-methyl-bis(2-pivaloyloxyethyl)amine, N-ethyl-bis[2-( m ethoxycarbonyloxy)ethyll amine, N-ethyl-bis[2-(tert-butoxycarbonyloxy)ethyl]amine, tris(methoxycarbonylmethyl)-amine, tris(ethoxycarbonylmethyl)amine, N-butyl-bis(methoxy-carbonylmethyl)amine, N-hexyl-bis(methoxycarbonylmethyl)-amine, and β-(diethylamino)-δ-valerolactone.

The basic compound is preferably formulated in an amount of 0.001 to 10 parts, and especially 0.01 to 1 part, per part of the photoacid generator. Less than 0.001 part of the basic compound may fail to achieve the desired effects thereof, while the use of more than 10 parts would result in too low a sensitivity and resolution.

### Other Components

In the resist composition, a compound bearing a ≡C—COOH group in a molecule may be blended. Exemplary, non-limiting compounds bearing a ≡C—COOH group include one or more compounds selected from Groups I and II below. Including this compound improves the PED stability of the resist and ameliorates edge roughness on nitride film substrates.

### Group I

Compounds in which some or all of the hydrogen atoms on the phenolic hydroxyl groups of the compounds of general formulas (A1) to (A10) below have been replaced with —R⁴⁰¹—COOH (wherein R⁴⁰¹ is a straight or branched alkylene of 1 to 10 carbon atoms), and in which the molar ratio C/(C+D) of phenolic hydroxyl groups (C) to ≡C—COOH groups (D) in the molecule is from 0.1 to 1.0.

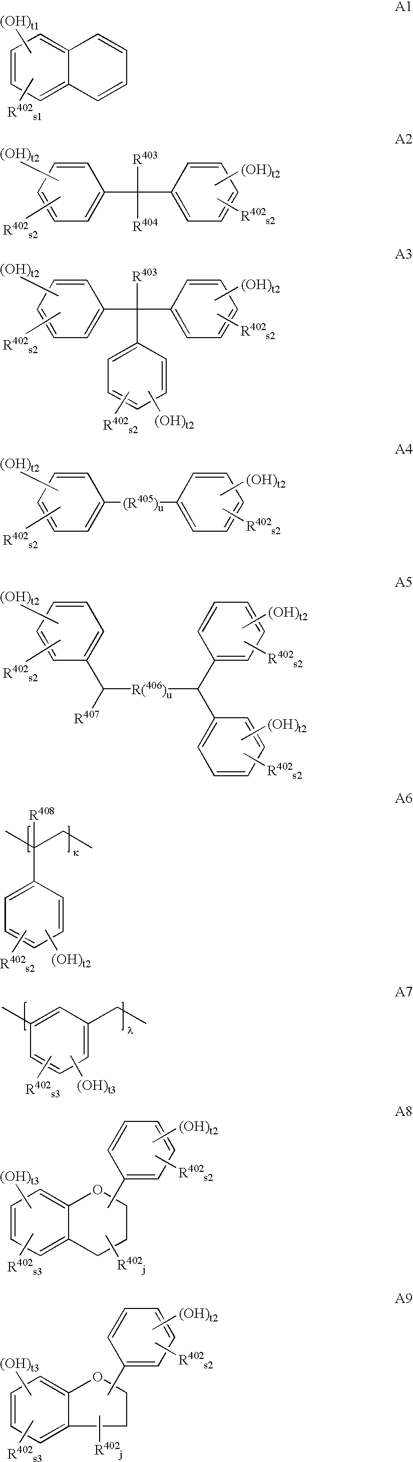

In these formulas, R⁴⁰⁸ is hydrogen or methyl; R⁴⁰² and R⁴⁰³ are each hydrogen or a straight or branched alkyl or alkenyl of 1 to 8 carbon atoms; R⁴⁰⁴ is hydrogen, a straight or branched alkyl or alkenyl of 1 to 8 carbon atoms, or a —(R⁴⁰⁹)ₕ—COOR′ group (R′ being hydrogen or —R⁴⁰⁹—COOH); R⁴⁰⁵ is —(CH₂)ᵢ— (wherein i is 2 to 10), an arylene of 6 to 10 carbon atoms, carbonyl, sulfonyl, an oxygen atom, or a sulfur atom; R⁴⁰⁶ is an alkylene of 1 to 10 carbon atoms, an arylene of 6 to 10 carbon atoms, carbonyl, sulfonyl, an oxygen atom, or a sulfur atom; R⁴⁰⁷ is hydrogen, a straight or branched alkyl or alkenyl of 1 to 8 carbon atoms, or a hydroxyl-substituted phenyl or naphthyl; R⁴⁰⁹ is a straight or branched alkylene of 1 to 10 carbon atoms; R⁴¹⁰ is hydrogen, a straight or branched alkyl or alkenyl of 1 to 8 carbon atoms, or a —R⁴¹¹—COOH group; R⁴¹¹ is a straight or branched alkylene of 1 to 10 carbon atoms; the letter j is an integer from 0 to 5; u and h are each 0 or 1; s1, t1, s2, t2, s3, t3, s4, and t4 are each numbers which satisfy s1+t1=8, s2+t2=5, s3+t3=4, and s4+t4 =6, and are such that each phenyl skeleton has at least one hydroxyl group; κ is a number such that the compound of formula (A6) may have a weight average molecular weight of 1,000 to 5,000; and λ is a number such that the compound of formula (A7) may have a weight average molecular weight of 1,000 to 10,000.

### Group II

Compounds of general formulas (A11) to (A15) below.

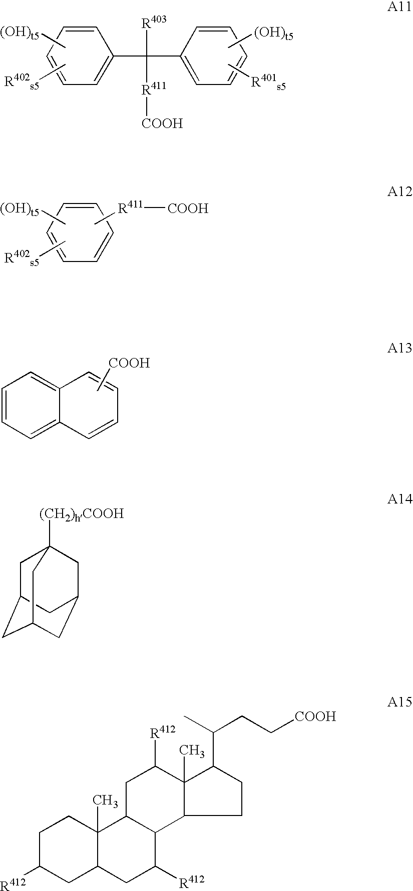

In these formulas, R⁴⁰², R⁴⁰³, and R⁴¹¹ are as defined above; R⁴¹² is hydrogen or hydroxyl; s5 and t5 are numbers which satisfy s5≧0, t5 ≧0, and s5+t5=5; and h′ is equal to 0 or 1.

Illustrative, non-limiting examples of the compound bearing a ≡C—COOH group include compounds of the general formulas AI-1 to AI-14 and AII-1 to AII-10 below.

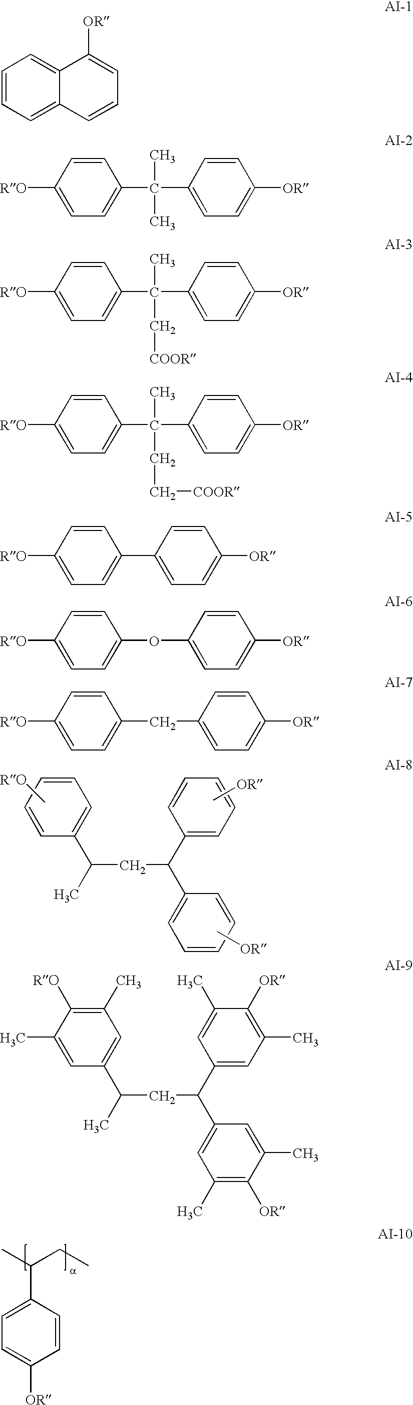

In the above formulas, R″ is hydrogen or a CH₂COOH group such that the CH₂COOH group accounts for 10 to 100 mol % of R″ in each compound, α and κ are as defined above.

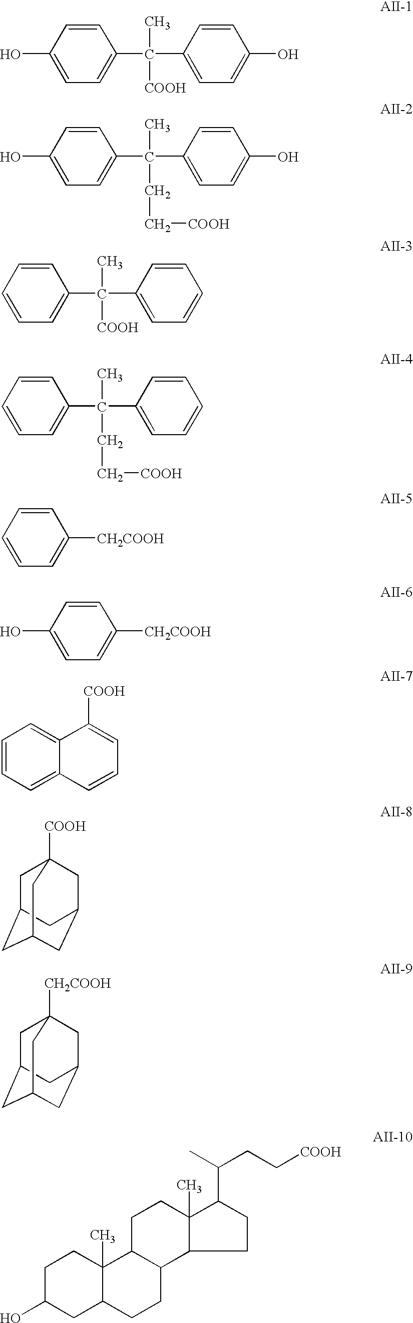

The compound bearing a ≡C—COOH group within the molecule may be used singly or as combinations of two or more thereof.

The compound bearing a ≡C—COOH group within the molecule is added in an amount ranging from 0 to 5 parts, preferably 0.1 to 5 parts, more preferably 0.1 to 3 parts, further preferably 0.1 to 2 parts, per 100 parts of the base resin. More than 5 parts of the compound can reduce the resolution of the resist composition.

The resist composition of the invention may additionally include an acetylene alcohol derivative for the purpose of enhancing the shelf stability. Preferred acetylene alcohol derivatives are those having the general formula (S1) or (S2) below.

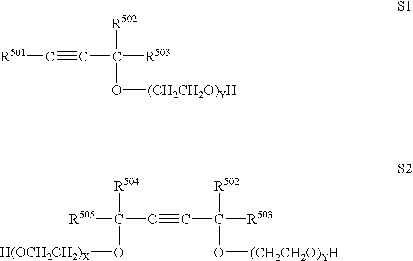

In the formulas, R⁵⁰¹, R⁵⁰², R⁵⁰³, R⁵⁰⁴, and R⁵⁰⁵ are each hydrogen or a straight, branched, or cyclic alkyl of 1 to 8 carbon atoms; and X and Y are each 0 or a positive number, satisfying 0≦X≦30, 0≦Y≦30, and 0≦X+Y≦40.

Preferable examples of the acetylene alcohol derivative include Surfynol 61, Surfynol 82, Surfynol 104, Surfynol 104E, Surfynol 104H, Surfynol 104A, Surfynol TG, Surfynol PC, Surfynol 440, Surfynol 465, and Surfynol 485 from Air Products and Chemicals Inc., and Surfynol E1004 from Nisshin Chemical Industry K. K.

The acetylene alcohol derivative is preferably added in an amount of 0.01 to 2% by weight, and more preferably 0.02 to 1% by weight, per 100% by weight of the resist composition. Less than 0.01% by weight would be ineffective for improving coating characteristics and shelf stability, whereas more than 2% by weight would result in a resist having a low resolution.

The resist composition of the invention may include optional ingredients, for example, a surfactant which is commonly used for improving the coating characteristics. Optional ingredients may be added in conventional amounts so long as this does not compromise the objects of the invention.

Nonionic surfactants are preferred, examples of which include perfluoroalkylpolyoxyethylene ethanols, fluorinated alkyl esters, perfluoroalkylamine oxides, perfluoroalkyl EO-addition products, and fluorinated organosiloxane compounds. Useful surfactants are commercially available under the trade names Florade FC-430 and FC-431 from Sumitomo 3M, Ltd., Surflon S-141 and S-145 from Asahi Glass Co., Ltd., Unidyne DS-401, DS-403 and DS-451 from Daikin Industry Co., Ltd., Megaface F-8151 from Dai-Nippon Ink & Chemicals, Inc., and X-70-092 and X-70-093 from Shin-Etsu Chemical Co., Ltd. Preferred surfactants are Florade FC-430 from Sumitomo 3M, Ltd. and X-70-093 from Shin-Etsu Chemical Co., Ltd.

Pattern formation using the resist composition of the invention may be carried out by a known lithographic technique. For example, the resist composition is applied onto a substrate such as a silicon wafer by spin coating or the like to form a resist film having a thickness of 0.2 to 2.0 μm, which is then pre-baked on a hot plate at 60 to 150° C. for 1 to 10 minutes, and preferably at 80 to 130° C. for 1 to 5 minutes. A patterning mask having the desired pattern is then placed over the resist film, and the film exposed through the mask to an electron beam or to high-energy radiation such as deep-UV rays, an excimer laser, or x-rays in a dose of about 1 to 200 mJ/cm², and preferably about 5 to 100 mJ/cm², then post-exposure baked (PEB) on a hot plate at 60 to 150° C. for 1 to 5 minutes, and preferably at 80 to 130° C. for 1 to 3 minutes. Finally, development is carried out using as the developer an aqueous alkali solution, such as a 0.1 to 5% (preferably 2 to 3%) aqueous solution of tetramethylammonium hydroxide (TMAH), this being done by a conventional method such as dipping, puddling, or spraying for a period of 0.1 to 3 minutes, and preferably 0.5 to 2 minutes. These steps result in the formation of the desired pattern on the substrate. Of the various types of high-energy radiation that may be used, the resist composition of the invention is best suited to fine pattern formation with, in particular, deep-UV rays having a wavelength of 248 to 193 nm, an excimer laser, x-rays, or an electron beam. The desired pattern may not be obtainable outside the upper and lower limits of the above range.

The resist composition comprising the inventive polymer as a base resin lends itself to micropatterning with electron beams or deep-UV rays since it is sensitive to high-energy radiation and has excellent sensitivity, resolution, and etching resistance. Especially because of the minimized absorption at the exposure wavelength of an ArF or KrF excimer laser, a finely defined pattern having sidewalls perpendicular to the substrate can easily be formed.

### EXAMPLE

Synthesis Examples and Examples are given below by way of illustration and not by way of limitation. The abbreviation Mw is a weight average molecular weight as measured by GPC using a polystyrene standard, and SEM is scanning electron microscope.

### Synthesis Example

Polymers within the scope of the invention were synthesized by the following procedure.

### Synthesis Example 1

Synthesis of Polymer 1

A mixture of 26.7 g of 2-norbornene-5-spiro-3′-(2′,5′-dioxooxolan) (synthesized by Diels-Alder reaction of itaconic anhydride with cyclopentadiene), 91.0 g of 2-ethyl-2-norbornyl 5-norbornene-2-carboxylate, 49.0 g of maleic anhydride and 71.4 g of 1,4-dioxane was heated at 60° C. To the solution was added 7.4 g of 2,2′-azobis(2,4-diemthylvaleronitrile). The solution was stirred for 15 hours while keeping at 60° C. The reaction solution was cooled to room temperature and dissolved in 500 ml of acetone, which with vigorous stirring, was added dropwise to 10 liters of isopropyl alcohol. The resulting solids were collected by filtration and dried in vacuum at 40° C. for 15 hours, obtaining a polymer, designated Polymer 1, in white powder solid form. The amount was 83.9 g with a yield of 50.3%.

### Synthesis Examples 2 to 16

Synthesis of Polymers 2-16

Polymers 2 to 16 were synthesized by the same procedure as above or a well-known procedure.

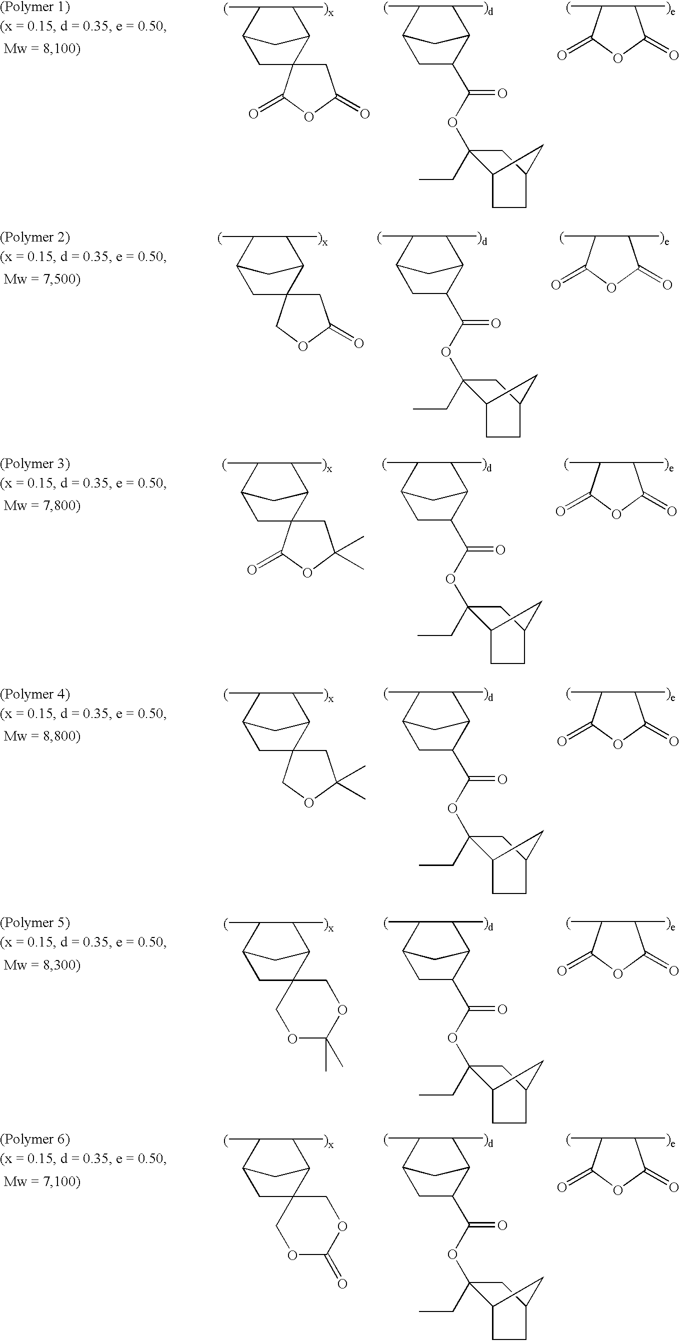

### EXAMPLE

Resist compositions were formulated using the inventive polymers as a base resin and examined for resolution.

### Examples 1-25 & Comparative Examples 1-4

Resist compositions were prepared by dissolving the inventive polymers (Polymers 1 to 16) or comparative polymers (Polymers 17 to 20 shown below), a photoacid generator (designated as PAG1 and 2), a dissolution regulator (designated as DRR1 to 4), a basic compound, and a compound having a ≡C—COOH group in the molecule (ACC1 and 2) in a solvent in accordance with the formulation shown in

TABLE 1
These compositions were each filtered through a
Teflon filter (pore diameter 0.2 μm), thereby giving resist
solutions.

| | | | |
|---|---|---|---|
| (Polymer 17) (a = 0.15, d = 0.35, e = 0.50, Mw = 8,500) | 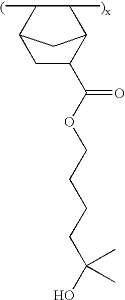 | 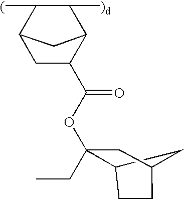 | 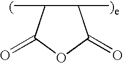 |
| (Polymer 18) (b = 0.15, d = 0.35, e = 0.50, Mw = 8,900) | 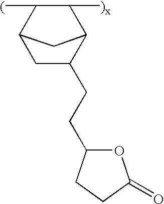 | 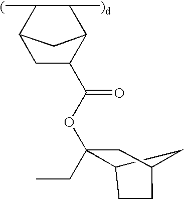 | 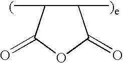 |
| (Polymer 19) (b = 0.25, d = 0.50, e = 0.25, Mw = 10,100) | 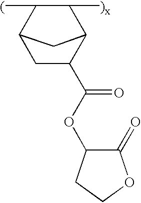 | 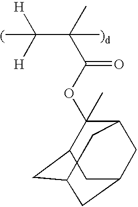 | 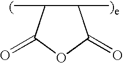 |
| (Polymer 20) (b = 0.50, d = 0.50, Mw = 12,500) | 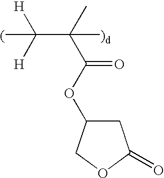 | 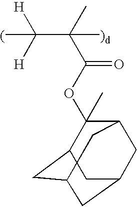 | |

(PAG 1)

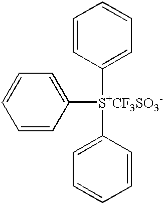

(PAG 2)

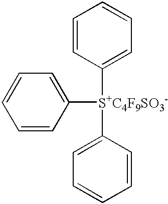

(DRR 1)

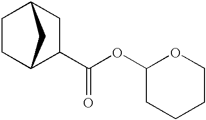

(DRR 2)

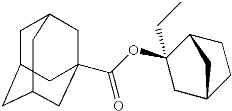

(DRR 3)

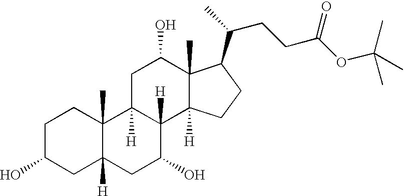

(DRR 4)

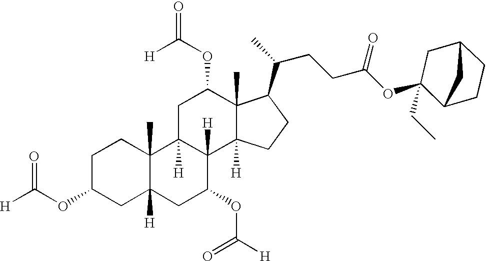

(ACC 1)

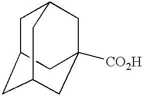

(ACC 2)

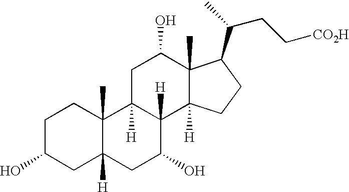

These resist solutions were spin-coated onto silicon wafers having an anti-reflection film (ARC25 by Nissan Chemical Co., Ltd., 77 nm) coated thereon, then heat treated at 130° C. for 90 seconds to give resist films having a thickness of 375 nm. The resist films were exposed using an ArF excimer laser stepper (Nikon Corporation; NA 0.55), then heat treated at 110° C. for 90 seconds, and puddle developed with a solution of 2.38% tetramethylammonium hydroxide in water for 60 seconds, thereby giving 1:1 line-and-space patterns. The developed wafers were cut, and the cross section was observed under a sectional SEM. The optimum exposure (Eop, mJ/cm²) was defined as the exposure which provided a 1:1 resolution at the top and bottom of a 0.25 μm line-and-space pattern. The resolution of the resist under evaluation was defined as the minimum line width (μm) of the lines and spaces that separated at this exposure. The shape of the resist pattern was classified into rectangular, rounded head, T-top, forward taper or reverse taper. Measured for evaluating line density dependency was the actual line width (nm) of 0.18 μm solitary lines at the exposure which provided a 1:1 resolution at the tope and bottom of a 0.18 μm line-and-space pattern.

The composition and test results of the resist materials in inventive Examples are shown in Table 1. The composition and test results of the resist materials in Comparative Examples are shown in Table 2. The solvents and basic compounds used are as follows. It is noted that the solvents each contained 0.01% by weight of surfactant FC-430 (Sumitomo 3M Co., Ltd.).

PGMEA: propylene glycol methyl ether acetate

CyHO: cyclohexanone

TEA: triethanolamine

TMMEA: trismethoxymethoxyethylamine

TMEMEA: trismethoxyethoxymethoxyethylamine

TABLE 1

| | | | | | | | | | Line |
|---|---|---|---|---|---|---|---|---|---|
| | | Photoacid | Dissolution | Basic | | | Reso- | | density |
| | Resin | generator | regulator | compound | Solvent | Eop, | lution, | | dependency |
| Example | (pbw) | (pbw) | (pbw) | (pbw) | (pbw) | mJ/cm² | μm | Shape | (nm) |
| 1 | Polymer 1 | PAG 1 | — | TEA | PGMEA | 17.0 | 0.18 | rectangular | 171 |
| | (80) | (1) | | (0.063) | (480) | | | | |
| 2 | Polymer 2 | PAG 1 | — | TEA | PGMEA | 16.0 | 0.18 | rectangular | 169 |
| | (80) | (1) | | (0.063) | (480) | | | | |
| 3 | Polymer 3 | PAG 1 | — | TEA | PGMEA | 16.0 | 0.18 | rectangular | 167 |
| | (80) | (1) | | (0.063) | (480) | | | | |
| 4 | Polymer 4 | PAG 1 | — | TEA | PGMEA | 17.0 | 0.18 | rectangular | 166 |
| | (80) | (1) | | (0.063) | (480) | | | | |
| 5 | Polymer 5 | PAG 1 | — | TEA | PGMEA | 16.0 | 0.18 | rectangular | 168 |
| | (80) | (1) | | (0.063) | (480) | | | | |
| 6 | Polymer 6 | PAG 1 | — | TEA | PGMEA | 17.0 | 0.18 | rectangular | 170 |
| | (80) | (1) | | (0.063) | (480) | | | | |
| 7 | Polymer 7 | PAG 1 | — | TEA | PGMEA | 20.0 | 0.22 | taper | 169 |
| | (80) | (1) | | (0.063) | (480) | | | | |
| 8 | Polymer 8 | PAG 1 | — | TEA | PGMEA | 16.0 | 0.18 | rectangular | 168 |
| | (80) | (1) | | (0.063) | (480) | | | | |
| 9 | Polymer 9 | PAG 1 | — | TEA | PGMEA | 18.0 | 0.19 | rectangular | 171 |
| | (80) | (1) | | (0.063) | (480) | | | | |
| 10 | Polymer 10 | PAG 1 | — | TEA | PGMEA | 19.0 | 0.19 | rectangular | 172 |
| | (80) | (1) | | (0.063) | (480) | | | | |
| 11 | Polymer 11 | PAG 1 | — | TEA | PGMEA | 15.0 | 0.17 | rectangular | 166 |
| | (80) | (1) | | (0.063) | (480) | | | | |
| 12 | Polymer 12 | PAG 1 | — | TEA | PGMEA | 16.0 | 0.17 | rectangular | 165 |
| | (80) | (1) | | (0.063) | (480) | | | | |
| 13 | Polymer 13 | PAG 1 | — | TEA | CyHO | 20.0 | 0.17 | rectangular | 164 |
| | (80) | (1) | | (0.063) | (560) | | | | |
| 14 | Polymer 14 | PAG 1 | — | TEA | CyHO | 25.0 | 0.19 | somewhat | 171 |
| | (80) | (1) | | (0.063) | (560) | | | taper | |
| 15 | Polymer 15 | PAG 1 | — | TEA | CyHO | 18.0 | 0.17 | rectangular | 165 |
| | (80) | (1) | | (0.063) | (560) | | | | |
| 16 | Polymer 16 | PAG 1 | — | TEA | CyHO | 17.0 | 0.17 | rectangular | 163 |
| | (80) | (1) | | (0.063) | (560) | | | | |
| 17 | Polymer 11 | PAG 2 | — | TEA | PGMEA | 16.0 | 0.17 | rectangular | 170 |
| | (80) | (1) | | (0.063) | (480) | | | | |
| 18 | Polymer 11 | PAG 2 | — | TMMEA | PGMEA | 16.0 | 0.17 | rectangular | 170 |
| | (80) | (1) | | (0.118) | (480) | | | | |
| 19 | Polymer 11 | PAG 2 | — | TMEMEA | PGMEA | 17.0 | 0.16 | rectangular | 169 |
| | (80) | (1) | | (0.173) | (480) | | | | |
| 20 | Polymer 2 | PAG 2 | DRR 1 | TEA | PGMEA | 15.0 | 0.18 | somewhat | 170 |
| | (70) | (1) | (10) | (0.063) | (480) | | | rounded head | |
| 21 | Polymer 2 | PAG 2 | DRR 2 | TEA | PGMEA | 15.0 | 0.18 | rectangular | 171 |
| | (70) | (1) | (10) | (0.063) | (480) | | | | |
| 22 | Polymer 2 | PAG 2 | DRR 3 | TEA | PGMEA | 20.0 | 0.19 | rectangular | 173 |
| | (70) | (1) | (10) | (0.063) | (480) | | | | |
| 23 | Polymer 2 | PAG 2 | DRR 4 | TEA | PGMEA | 16.0 | 0.17 | rectangular | 169 |
| | (70) | (1) | (10) | (0.063) | (480) | | | | |
| 24 | Polymer 2 | PAG 2 | ACC 1 | TEA | PGMEA | 16.0 | 0.18 | somewhat | 172 |
| | (80) | (1) | (4) | (0.063) | (480) | | | rounded head | |
| 25 | Polymer 2 | PAG 2 | ACC 2 | TEA | PGMEA | 19.0 | 0.19 | rectangular | 175 |
| | (80) | (1) | (4) | (0.063) | (480) | | | | |

TABLE 2

| | | | | | | | | | Line |
|---|---|---|---|---|---|---|---|---|---|
| Compar- | | Photoacid | Dissolution | Basic | | | Reso- | | density |
| ative | Resin | generator | regulator | compound | Solvent | Eop, | lution, | | dependency |
| Example | (pbw) | (pbw) | (pbw) | (pbw) | (pbw) | mJ/cm² | μm | Shape | (nm) |
| 1 | Polymer 17 | PAG 1 | — | TEA | PGMEA | 15.0 | 0.19 | rectangular | 152 |
| | (80) | (1) | | (0.063) | (480) | | | | |
| 2 | Polymer 18 | PAG 1 | — | TEA | PGMEA | 16.0 | 0.19 | rectangular | 158 |
| | (80) | (1) | | (0.063) | (480) | | | | |
| 3 | Polymer 19 | PAG 1 | — | TEA | PGMEA | 18.0 | 0.20 | somewhat | 160 |
| | (80) | (1) | | (0.063) | (480) | | | taper | |
| 4 | Polymer 20 | PAG 1 | — | TEA | PGMEA | 17.0 | 0.20 | somewhat | 155 |
| | (80) | (1) | | (0.063) | (480) | | | taper | |

It is seen from Tables 1 and 2 that the resist compositions within the scope of the invention have a high sensitivity, high resolution and minimized line density dependency upon ArF excimer laser exposure.

Japanese Patent Application No. 2001-150535 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A polymer comprising recurring units of the following general formulae (1) and (2) and units of at least one type which are decomposable under acidic conditions to generate carboxylic acid, and having a weight average molecular weight of 1,000 to 500,000, 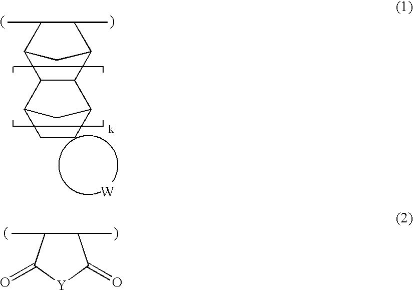
wherein W is a divalent group having 2 to 15 carbon atoms which forms a cyclic ether, cyclic ketone, lactone, cyclic carbonate, cyclic acid anhydride or cyclic imide of 5- or 6-membered ring with the carbon atom to which it is bonded, k is 0 or 1, and
Y is —O— or —(NR¹)— wherein R¹ is hydrogen or a straight, branched or cyclic alkyl group of 1 to 15 carbon atoms.

2. The polymer of claim 1 wherein the units of at least one type which are decomposable under acidic conditions to generate carboxylic acid include recurring units of the following general formula (3): 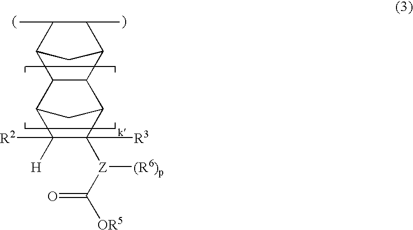
wherein R² is hydrogen, methyl or CH₂CO₂R⁴,
R³ is hydrogen, methyl or CO₂R⁴,
R⁴ which may be identical or different in R² and R³ is a straight, branched or cyclic alkyl group of 1 to 15 carbon atoms,
R⁵ is an acid labile group,
R⁶ is selected from the class consisting of a halogen atom, a hydroxyl group, a straight, branched or cyclic alkoxy, acyloxy or alkylsulfonyloxy group of 1 to 15 carbon atoms, and a straight, branched or cyclic alkoxycarbonyloxy or alkoxyalkoxy group of 2 to 15 carbon atoms, in which some or all of the hydrogen atoms on constituent carbon atoms may be substituted with halogen atoms,
Z is a single bond or a straight, branched or cyclic (p+2)-valent hydrocarbon group of 1 to 5 carbon atoms, in which at least one methylene may be substituted with oxygen to form a chain-like or cyclic ether or two hydrogen atoms on a common carbon may be substituted with oxygen to form a ketone,
k′ is 0 or 1, and
p is 0, 1 or 2.

3. The polymer of claim 1 wherein the units of at least one type which are decomposable under acidic conditions to generate carboxylic acid include recurring units of the following general formula (4): 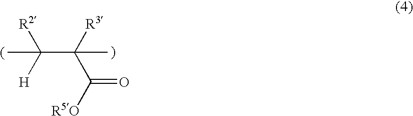
wherein R^{2′} is hydrogen, methyl or CH₂CO₂R^{4′},
R^{3′} is hydrogen, methyl or CO₂R^{4′},
R^{4′} which may be identical or different in R^{2′} and R^{3′} is a straight, branched or cyclic alkyl group of 1 to 15 carbon atoms, and
R^{5′} is an acid labile group.

4. A resist composition comprising the polymer of claim 1.

5. A process for forming a resist pattern comprising the steps of:
applying the resist composition of claim 4 onto a substrate to form a coating,
heat treating the coating and then exposing it to high-energy radiation or electron beams through a photo mask, and
optionally heat treating the exposed coating and developing it with a developer.
